(19) United States
(12) Patent Application Publication
(10) Pub. No.: US 2009/0321944 A1
(43) Pub. Date: Dec. 31, 2009

(54) SEMICONDUCTOR DEVICE WITH IMPROVED INTERCONNECTION OF CONDUCTOR PLUG

(75) Inventor: Yoshiyuki SUZUKI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/552,584

(22) Filed: Sep. 2, 2009

Related U.S. Application Data
(62) Division of application No. 10/950,618, filed on Sep. 28, 2004.

(30) Foreign Application Priority Data
May 14, 2004 (JP) 2004-144619

(51) Int. Cl. H01L 23/48; H01L 21/768

(52) U.S. Cl. 257/773; 438/672; 257/E23.011; 257/E21.585

(57) ABSTRACT

The semiconductor device comprises a conductor plug 20 and an interconnection 22 having one end connected directly to an upper part of the conductor plug 20. The conductor plug 20 has a projection 20a formed at the upper part of the conductor plug 20 integral with the conductor plug 20 and having a projection 20a projected in the direction from one end of the interconnection 22 toward the inside thereof. The interconnection 22 is connected to at least the projection 20a of the conductor plug 20. Because of the projection 20a of the conductor plug 20 is formed, even when the pattern of the interconnection 22 is largely set back, the connection between the interconnection 22 and the conductor plug 20 can be ensured at least at the projection 20a. Thus, even when the pattern of the interconnection 22 is largely set back due to the micronization and high density of the interconnection 22, the interconnection 22 and the conductor plug 20 can be connected to each other without failure. Accordingly, the present invention can provide a semiconductor device which can realize micronization and high integration while ensuring reliability.

### CROSS-REFERENCE TO RELATED APPLICATION

This is a divisional application of U.S. patent application Ser. No. 10/950,618, filed on Sep. 28, 2004, currently pending, which claims the benefit of priority of Japanese Patent Application No. 2004-144619, filed on May 14, 2004, the contents being incorporated herein by reference.

### BACKGROUND OF THE INVENTION

The present invention relates to a semiconductor device and a method for fabricating the semiconductor device, more specifically a semiconductor device which can realize micronization and high integration with the reliability ensured, and a method for fabricating the semiconductor device.

For higher freedom of design, higher integration and down-size of chips, multilayer interconnection technique has been conventionally used.

For further efficiency of the multilayer interconnection, the interconnection width, the interconnection pitch, and the alignment margin between conductor plugs and interconnections go on being reduced.

FIGS. 27A and 27B are conceptual views of the proposed semiconductor device. FIG. 27A is a plan view, and FIG. 27B is a sectional view.

As illustrated in FIGS. 27A and 27B, an interconnection 212 is formed on a semiconductor substrate 210. An inter-layer insulation film 214 is formed on the semiconductor substrate 210 with the interconnection 212 formed on. A contact hole 216 and a contact hole 230 are formed in the inter-layer insulation film 214 respectively down to the interconnection 212. Conductor plugs 220, 226 are formed respectively in the contact holes 216, 230.

On the inter-layer insulation film 214 with the conductor plugs 220, 226 buried in, interconnections 222, 228 are formed. The parts of the interconnections 222, 228 indicated by the broken lines are patterns of the interconnections in the design stage. The interconnections 222, 228 are formed by patterning a conductor film to be the interconnections 222, 228 with a photoresist film (not shown) as the mask. In exposing the patterns for forming the interconnections 222, 228 on the photoresist film, evenparts which are not to be exposed are exposed by the diffracted light, and the interconnection patterns actually exposed on the photoresist film have the ends set back from the interconnection patterns in the design stage.

In the design stage, the patterns of the interconnections 222, 228 are set longer in advance in consideration of the set-back of the patterns thereof. Even when the patterns of the interconnections 222, 228 are set back, the connection between the interconnections 222, 228 and the conductor plugs 220, 226 can be ensured.

Following references disclose the background art of the present invention.

[Patent Reference 1]

Specification of Japanese Patent Application Unexamined Publication No. Hei 11-135630

[Patent Reference 2]

Specification of Japanese Patent Application Unexamined Publication No. Hei 10-27848

[Patent Reference 3]

Specification of Japanese Patent Application Unexamined Publication No. 2002-343861

[Patent Reference 4]

Specification of Japanese Patent Application Unexamined Publication No. 2002-246466

### SUMMARY OF THE INVENTION

When the width of the interconnections are set smaller so as to satisfy the requirement of the micronization, the set-back of the interconnection patterns are larger. In order to satisfy the requirement of higher integration, the interconnection pitch is set smaller, it is necessary set higher exposure energy for the prevention of the short-circuit between the interconnections. The set-back of the interconnection patterns is larger, and as illustrated in FIG. 28, the connections between the interconnections 222, 228 and the conductor plugs 220, 226 cannot be ensured. FIG. 28 is a sectional view of the case, where the interconnections and the conductor plugs have failed to ensure the connection. Here, it is an idea to design the interconnection patterns longer in consideration of the set-back of the interconnection patterns. However, according to the design rules, the end of the interconnection 222 and the end of the interconnection 228 must be spaced from each other by a certain distance L1 or more in the design stage. Accordingly, there is a limit to forming the interconnections 222, 228 longer in consideration of the set-back of the patterns of the interconnections 222, 228.

An object of the present invention is to provide a semiconductor device which can realize micronization and high integration while ensuring high reliability, and a method for fabricating the semiconductor device.

According to one aspect of the present invention, there is provided a semiconductor device comprising a conductor plug, and an interconnection having one end directly connected to an upper part of the conductor plug, the conductor plug having at the upper part thereof a projection which is formed integral with the conductor plug and is projected in the direction from said one end of the interconnection toward the inside of the interconnection, and the interconnection being connected to at least the projection of the conductor plug.

According to another aspect of the present invention, there is provided a semiconductor device comprising: a conductor plug; another conductor plug arranged, spaced from the conductor plug; a conductor formed integral with the conductor plug and said another conductor plug and connecting an upper part of the conductor plug and an upper part of said another conductor plug with each other; and an interconnection formed along the conductor, the interconnection being connected directly to at least the conductor.

According to further another aspect of the present invention, there is provided a method for fabricating a semiconductor device comprising the steps of: forming an insulation layer over a semiconductor substrate; forming a contact hole in the insulation layer; forming a trench integral with the contact hole in the insulation layer, the trench being shallower than the contact hole and extended from the contact hole in a first direction; burying a conductor plug having a projection projected in the trench in the trench and the contact hole; and forming a conductor film directly on the insulation layer and the conductor plug; patterning the conductor film to form an interconnection of the conductor film having one end connected to at least the projection, in the step of forming an interconnection, the interconnection being formed so that the direction from said one end of the interconnection toward the inside thereof agrees with the first direction.

According to further another aspect of the present invention, there is provided a method for fabricating a semiconductor device comprising the steps of: forming an insulation layer over a semiconductor substrate; forming in the insulation layer a trench extended in a first direction from a first position; forming a contact hole deeper than the trench integrally with the trench in the insulation layer at said first position; burying a conductor plug having a projection projected in the trench in the contact hole and the trench; forming a conductor film on the insulation layer and the contact layer; and patterning the conductor film to form an interconnection of the conductor film having one end connected to at least the projection, in the step of forming an interconnection, the interconnection being formed so that the direction from said one end of the interconnection toward the inside thereof agrees with the first direction.

According to further another aspect of the present invention, there is provided a method for fabricating a semiconductor device comprising the steps of: forming an insulation layer over a semiconductor substrate; forming a first contact hole and a second contact hole in the insulation layer; forming a trench integral with the first and the second contact holes in the insulation layer, the trench being shallower than the first and the second contact holes and extended from the first contact hole to the second contact hole; burying a conductor plug in the first contact hole, burying another conductor plug in the second contact hole and burying a conductor in the trench; forming a conductor film on the insulation layer, the conductor plug, said another conductor plug and the conductor; and patterning the conductor film to form along the conductor an interconnection of the conductor film connected to at least the conductor.

According to further another aspect of the present invention, there is provided a method for fabricating a semiconductor device comprising the steps of: forming an insulation layer over a semiconductor substrate; forming in the insulation layer a trench extended from a first position to a second position; forming a first contact hole deeper than the trench integrally with the trench in the insulation layer at said first position and forming a second contact hole deeper than the trench integrally with the trench in the insulation layer at said second position; burying a conductor plug in the first contact hole, burying another conductor plug in the second contact hole and burying a conductor in the trench; forming a conductor film on the insulation layer, the conductor plug, said another conductor plug and the conductor; and patterning the conductor film to form an interconnection of the conductor film along the conductor, connected to at least the conductor.

According to the present invention, the conductor plug has the projection which is projected in the direction from one end of the interconnection toward the inside thereof, whereby even when the pattern of the interconnection is largely set back, the connection between the interconnection and the conductor plug can be ensured at least at the projection. Thus, according to the present invention, even when the patterns of interconnections are largely set back due to the micronization and high density of the interconnections, the interconnections and the conductor plugs can be connected to each other without failure. Thus, the present invention can provide a semiconductor device which can realize micronization and high integration while ensuring reliability.

### BRIEF DESCRIPTION OF THE DRAWINGS

FIGS. 1A and 1B are diagrammatic views of the semiconductor device according to a first embodiment of the present invention.

FIGS. 2A and 2B are diagrammatic views of the semiconductor device according to a second embodiment of the present invention.

FIGS. 3A and 3B are diagrammatic views of the semiconductor device according to a third embodiment of the present invention.

FIG. 4 is a sectional view of the semiconductor device according to a fourth embodiment of the present invention.

FIGS. 5A and 5B are sectional views of the semiconductor device according to the fourth embodiment of the present invention in the steps of the method for fabricating the semiconductor device, which illustrate the method (Part 1).

FIGS. 6A and 6B are sectional views of the semiconductor device according to the fourth embodiment of the present invention in the steps of the method for fabricating the semiconductor device, which illustrate the method (Part 2).

FIGS. 7A and 7B are sectional views of the semiconductor device according to the fourth embodiment of the present invention in the steps of the method for fabricating the semiconductor device, which illustrate the method (Part 3).

FIGS. 8A and 8B are sectional views of the semiconductor device according to the fourth embodiment of the present invention in the steps of the method for fabricating the semiconductor device, which illustrate the method (Part 4).

FIGS. 9A and 9B are sectional views of the semiconductor device according to the fourth embodiment of the present invention in the steps of the method for fabricating the semiconductor device, which illustrate the method (Part 5).

FIGS. 10A and 10B are sectional views of the semiconductor device according to the fourth embodiment of the present invention in the steps of the method for fabricating the semiconductor device, which illustrate the method (Part 6).

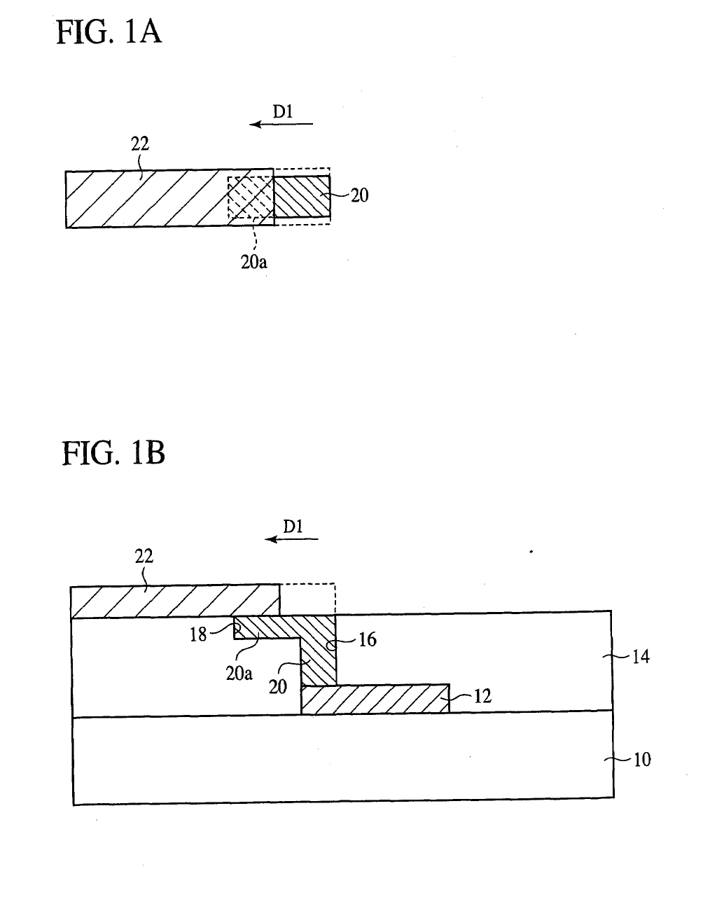

FIGS. 1A and 11B are sectional views of the semiconductor device according to the fourth embodiment of the present invention in the steps of the method for fabricating the semiconductor device, which illustrate the method (Part 7).

FIGS. 12A and 12B are sectional views of the semiconductor device according to one modification of the fourth embodiment of the present invention in the steps of the method for fabricating the semiconductor device, which illustrate the method.

FIG. 13 is a sectional view of the semiconductor device according to a fifth embodiment of the present invention.

FIGS. 14A and 14B are sectional views of the semiconductor device according to the fifth embodiment of the present invention in the steps of the method for fabricating the semiconductor device, which illustrate the method (Part 1).

FIGS. 15A and 15B are sectional views of the semiconductor device according to the fifth embodiment of the present invention in the steps of the method for fabricating the semiconductor device, which illustrate the method (Part 2).

FIG. 16 is sectional views of the semiconductor device according to the fifth embodiment of the present invention in the steps of the method for fabricating the semiconductor device, which illustrate the method (Part 3).

FIG. 17 is a sectional view of the semiconductor device according to one modification of the fifth embodiment of the present invention.

FIGS. 18A and 18B are sectional views of the semiconductor device according to the modification of the fifth embodiment of the present invention in the steps of the method for fabricating the semiconductor device, which illustrate the method (Part 1).

FIGS. 19A and 19B are sectional views of the semiconductor device according to the modification of the fifth embodiment of the present invention in the steps of the method for fabricating the semiconductor device, which illustrate the method (Part 2).

FIG. 20 is sectional views of the semiconductor device according to the modification of the fifth embodiment of the present invention in the steps of the method for fabricating the semiconductor device, which illustrate the method (Part 3).

FIGS. 21A and 21B are diagrammatic views of the semiconductor device according to a sixth embodiment of the present invention.

FIG. 22 is a sectional view of the semiconductor device according to a seventh embodiment of the present invention.

FIG. 23 is a plan view of the semiconductor device according to the seventh embodiment of the present invention.

FIGS. 24A to 24C are conceptual views of a mask pattern in the step of mask pattern forming method according to an eighth embodiment of the present invention (Part 1).

FIGS. 25A to 25C are conceptual views of a mask pattern in the steps of mask pattern forming method according to the eighth embodiment of the present invention (Part 2).

FIGS. 26A and 26B are sectional views of the mask pattern according to the eighth embodiment of the present invention.

FIGS. 27A and 27B are diagrammatic views of the proposed semiconductor device.

FIG. 28 is a sectional view of a case that the interconnections and the conductor plugs have failed to ensure the connection.

### DETAILED DESCRIPTION OF THE INVENTION

### A FIRST EMBODIMENT

The semiconductor device according to a first embodiment of the present invention will be explained with reference to FIGS. 1A and 1B. FIGS. 1A and 1B are diagrammatic views of the semiconductor device according to the present embodiment. FIG. 1A is a plan view, and FIG. 1B is a sectional view.

As illustrated in FIGS. 1A and 1B, an interconnection 12 is formed on a semiconductor substrate 10.

On the semiconductor substrate 10 with the interconnection 12 formed on, an inter-layer insulation film (insulation layer) 14 is formed, covering the interconnection 12.

A contact hole 16 is formed in the inter-layer insulation film 14 down to the interconnection 12. In the inter-layer insulation film 14, a trench 18 is formed, extended from the contact hole 16 only in a first direction D1. The trench 18 is formed shallower than the contact hole 16. The trench 18 is integral with the contact hole 16.

In the contact hole 16 and the trench 18, a conductor plug 20 having a projection 20a projected into the trench 18 is buried. The projection 20a is formed of one and the same conductor film integral with the conductor plug 20. The projection 20a is projected only in the first direction D1.

On the inter-layer insulation film 14 and the conductor plug 20, an interconnection 22 is formed. One end of the interconnection 22 is connected directly to at least the projection 20a of the conductor plug 20. The direction from said one end of the interconnection 22 toward the inside thereof agrees with the first direction D1.

The part of the interconnection 22 indicated by the broken line is the pattern of the interconnection 22 in the design stage. The part of the interconnection indicated by the solid line is the pattern of the actually formed interconnection 22. As illustrated in FIGS. 1A and 1B, the pattern of the actually formed interconnection 22 has the end largely set back in comparison with the pattern of the interconnection 22 in the design stage.

The end of the interconnection 22 is largely set back for the following reason. That is, the interconnection 22 is formed by patterning, with a photoresist film as the mask, a conductor film which is to form the interconnection 22. When the interconnection pattern is exposed on the photoresist film, even the part which is not to be exposed by the diffracted light, and the interconnection pattern actually exposed on the photoresist film has the end set back from the interconnection pattern in the design stage. Furthermore, when the width of the interconnection pattern is set smaller so as to satisfy the requirement of micronization, the set-back of the pattern of the interconnection pattern is much larger.

In the present embodiment, the conductor plug 20 has the projection 20a projected in the first direction D1, and the direction of the interconnection from the end toward the inside thereof agrees with the first direction D1, whereby even when the interconnection pattern is largely setback from the design value, the connection between the interconnection 22 and the conductor plug 20 is ensured at least at the projection 20a. Thus, according to the present embodiment, even when the pattern of the interconnection is largely set back, the interconnection and the conductor plug can be connected to each other without failure.

The projection 20a is projected only in the first direction D1 in the present embodiment for the following reason. That is, when the projection 20a is formed, projected not only in the first direction D1 but also in other directions, the pitch of the conductor plugs and the pitch of the interconnections must be set larger. Then, this cannot contribute to the requirements of micronizatin and higher integration of semiconductor devices. On the other hand, the first direction D1 agrees with the direction which is from one end of the interconnection 22 toward the inside thereof, and the projection 20a is projected accordingly below the interconnection 22. Thus, the projection of the projection 20a in the first direction D1 causes no special problem. For this reason, the projection 20a is projected in the first direction D1 in the present embodiment.

Thus, the semiconductor device according to the present embodiment is constituted.

The semiconductor device according to the present embodiment is characterized mainly in that the conductor plug 20 has the projection 20a projected in the first direction D1, the direction from one end of the interconnection 22 toward the inside thereof agrees with the first direction D1, and said one end of the interconnection 22 is connected directly to the conductor plug 20 at least at the projection 20a.

According to the present embodiment, the conductor plug 20 has the projection 20a projected in the first direction D1, and the direction from one end of the interconnection 22 toward the inside thereof agrees with the first direction D1, whereby even when the pattern of the interconnection 22 is largely set back, the connection between the interconnection 22 and the conductor plug 20 can be ensured at least at the projection 20a. Thus, the semiconductor device according to the present embodiment can realize micronization and high integration while ensuring reliability.

The structure of the semiconductor device according to the present embodiment is apparently different from the dual damascene structure, in which a conductor plug and an interconnection are buried integral in an inter-layer insulation film with a contact hole and a trench formed integral therein. That is, in the dual damascene structure, a conductor itself buried in a trench is an interconnection. Accordingly, in the dual damascene structure, the depth of the trench must be strictly set. To set a depth of the trench strictly, an etching stopper film, etc. must be formed on an inter-layer insulation film. This makes the fabrication process complicated. In the present embodiment, wherein the projection 20a is formed independently of the interconnection 22, the dept of the trench 18 for the projection 20a to be buried in must not be set strictly. Thus, the present embodiment does not make the fabrication process complicated. In the dual damascene structure, wherein an interconnection is buried in a trench, when the trench is formed, precise design rules considering burying characteristics must be applied. In contrast to this, in the present embodiment, what is buried in the trench 18 is only the projection 20a of the conductor plug 20, and as long as the projection 20a and the interconnection 22 can be connected to each other, strict design rules for forming the trench 18 are not necessary. Thus, the present invention is completely different form the dual damascene structure.

### A SECOND EMBODIMENT

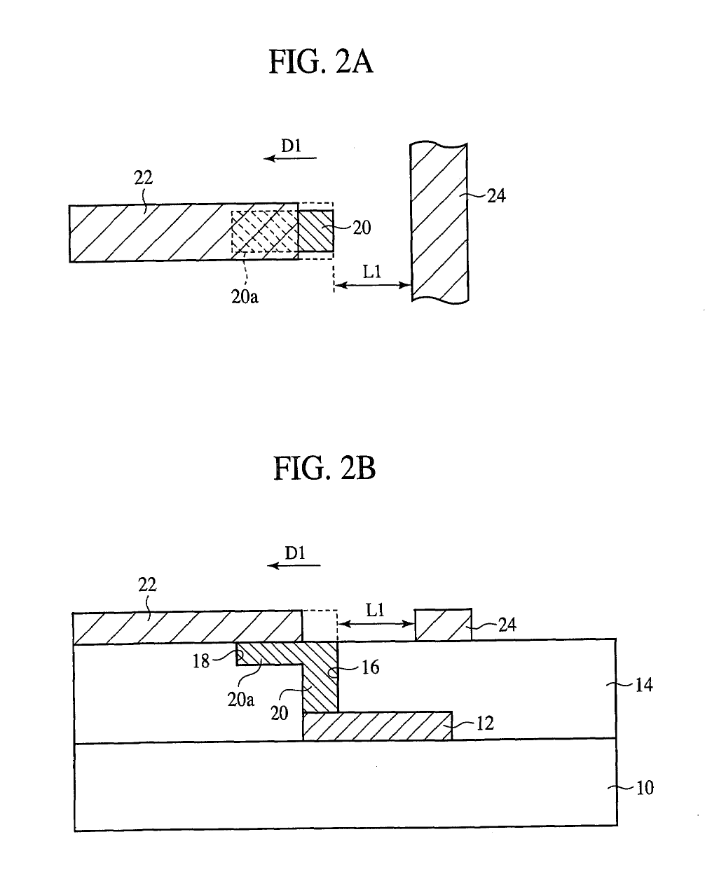

The semiconductor device according to a second embodiment of the present invention will be explained with reference to FIGS. 2A and 2B. FIGS. 2A and 2B are diagrammatic views of the semiconductor device according to the present embodiment. FIG. 2A is a plan view, and the FIG. 2B is a sectional view. The same members of the present embodiment as those of the semiconductor device according to the first embodiment illustrated in FIGS. 1A and 1B are represented by the same reference numbers not to repeat to simplify their explanation.

The semiconductor device according to the present embodiment is characterized mainly in that another interconnection 24 is formed on the inter-layer insulation film 14, and a part of said another interconnection 24 is very near the end of the interconnection 22.

As illustrated in FIGS. 2A and 2B, said another interconnection 24 is formed on the inter-layer insulation film 14. The longitudinal direction of the interconnection 24 is substantially perpendicular to the longitudinal direction of the interconnection 22.

The part of the interconnection 22 indicated by the broken line is the pattern of the interconnection 22 in the design stage. According to the rules for the photolithography, the end of the interconnection 22 and said another interconnection 24 must be spaced from each other by a certain distance L1 or more in the design stage. Accordingly, there is a limit to forming in advance the interconnection 22 longer in consideration of the set-back of the pattern thereof. In the present embodiment, the conductor plug 20 has a projection 20a projected in a first direction D1, and the direction from one end of the interconnection 22 toward the inside thereof agrees with the first direction D1, whereby even when the pattern of the interconnection 22 is set back largely from the design value, the connection between the interconnection 22 and the conductor plug 20 can be ensured at least at the projection 20a. Thus, according to the present embodiment, even in a case where the interconnection 22 cannot be formed longer in advance in consideration of the set-back of the pattern thereof, the interconnection 22 and the conductor plug 20 can be connected to each other without failure.

### A THIRD EMBODIMENT

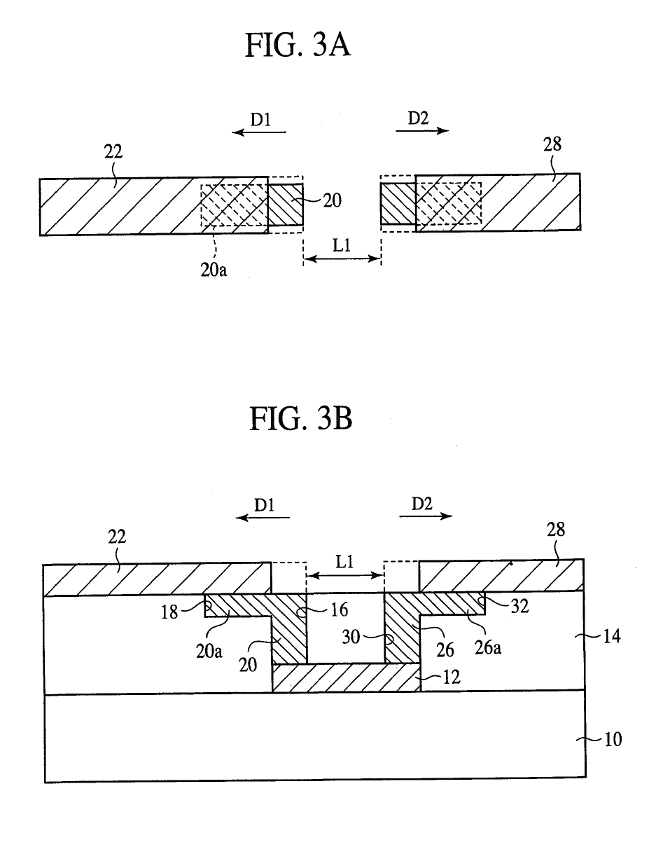

The semiconductor device according to a third embodiment of the present invention will be explained with reference to FIGS. 3A and 3B. FIGS. 3A and 3B are diagrammatic views of the semiconductor device according to the present embodiment. The same members of the present embodiment as those of the semiconductor device according to the first or the second embodiment are represented by the same reference numbers not to repeat or to simplify their explanation.

The semiconductor device according to the present embodiment is characterized mainly in that another conductor plug 26 is buried adjacent to a conductor plug 20, and said another conductor plug 26 has another projection 26a projected in a second direction D2, said interconnection 28 is connected to said conductor plug 26, and the direction from the end of said another interconnection 28 toward the inside thereof agrees with the second direction D2.

As illustrated in FIGS. 3A and 3B, a contact hole 30 is formed in the inter-layer insulation film 14 down to the interconnection 12. In the inter-layer insulation film 14, a trench 32 is formed, extend from the contact hole 30 in the second direction D2. The second direction D2 is opposite to the first direction D1. The trench 32 is shallower than the contact hole 30. The trench 32 is formed integral with the contact hole 30.

Another conductor plug 26 is buried adjacent to the conductor plug 20 in the contact hole 30 and the trench 32. The conductor plug 26 has the projection 26a projected in the trench 32. The projection 26a is formed of one and the same conductor film as the conductor plug 26. The projection 26a is projected in the second direction D2.

On the inter-layer insulation film 14, another interconnection 28 is formed. The end of the interconnection 22 and the end of said another interconnection 28 are opposed to each other.

The part of the interconnection 28 indicated by the broken line is the pattern of the interconnection 28 in the design stage. According to the photolithography rules, the end of the interconnection 22 and the end of said another interconnection 28 must be spaced from each other by a certain distance L1 or more in the design stage. Accordingly, there is a limit to forming in advance the interconnections 22, 28 longer in consideration of the set-back of the patterns of the interconnections 22, 28. In the present embodiment, wherein the conductor plug 26 has the projection 26a projected in the second direction D2, and the direction from the end of the interconnection 28 toward the inside there of agrees with the second direction D2, whereby even when the pattern of the interconnection 28 is largely set back from the design value, the connection between the interconnection 28 and the conductor plug 26 is ensured at least at the projection 26a. Thus, according to the present embodiment, even when the patterns of the interconnections are largely set back, the interconnections and the conductor plugs can be connected without failure.

### A FOURTH EMBODIMENT

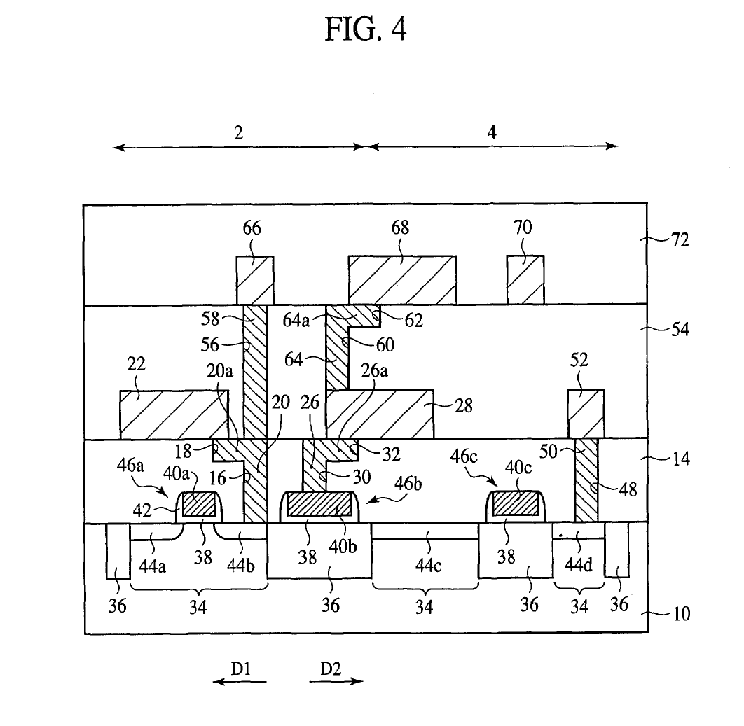

The semiconductor device according to a fourth embodiment of the present invention and the method for fabricating the semiconductor device will be explained with reference to FIGS. 4 to 11B. FIG. 4 is a sectional view of the semiconductor device according to the present embodiment. The same members of the present embodiment as those of the semiconductor device according to the first to the third embodiments illustrated in FIGS. 1A to 3B are represented by the same reference numbers not to repeat or to simplify their explanation.

### (The Semiconductor Device)

First, the semiconductor device according to the present embodiment will be explained with reference to FIG. 4. In FIG. 4, a memory cell region 2 is illustrated in the left region of the drawing. In the right region of the drawing, a logic circuit (peripheral circuit) region 4 is illustrated. In the memory cell region 2, the respective devices, such as transistors, etc. are formed in a relatively high density. On the other hand, in the logic circuit region 4, the respective device, such as transistors, etc., are formed in a relatively low density.

As illustrated in FIG. 4, device isolation region 36 for defining device regions 34 are formed in a semiconductor substrate 10.

A gate insulation film 38 is formed on the semiconductor substrate 10.

Gate electrodes 40a, 40b, 40c are formed on the gate insulation film 38.

A sidewall insulation film 42 is formed on the side walls of the gate electrode 40.

In the semiconductor substrate 10 on both sides of the gate electrodes 40 with the sidewall insulation film 42 formed on, a source/drain diffused layer 44a, 44b, 44c, 44d is formed.

Thus, transistors 46a, 46b, 46c including the gate electrodes 40 and the source/drain diffused layer 44 are formed.

An inter-layer insulation film 14 is formed on the semiconductor substrate 10 with the transistors 46 formed on.

In the inter-layer insulation film 14, a contact hole 16 is formed down to the source/drain diffused layer 44. In the inter-layer insulation film 14, a trench 18 which is shallower than the contact hole 16 is formed. A conductor plug 20 is buried in the trench 18 and the contact hole 16. The conductor plug 20 has a projection 20a projected in a first direction D1.

In the inter-layer insulation film 14, a contact hole 30 is formed down to the gate electrode 40b. In the inter-layer insulation film 14, a trench 32 which is shallower than the contact hole 30 is formed. A conductor plug 26 is buried in the trench 32 and the contact hole 30. The conductor plug 26 has a projection 26a projected in a second direction D2.

In the inter-layer insulation film 14, a contact hole 48 is formed down to the source/drain diffused layer 44d. A conductor plug 50 is buried in the contact hole 48.

An interconnection 22 is formed on the inter-layer insulation film 14 in the memory cell region 2. One end of the interconnection 22 is connected to the conductor plug 20. The direction from said one end of the interconnection 22 toward the inside thereof agrees with the first direction D1. In the semiconductor device according to the present embodiment, because of the interconnection 28 formed opposed to the interconnection 22, it is impossible to form in advance the interconnection 22 longer in consideration of the set-back of the pattern of the interconnection 22. However, the conductor plug 20 has the projection 20a projected in the first direction D1, and the direction from one end of the interconnection 22 toward the inside thereof agrees with the first direction D1, whereby even when the pattern of the interconnection 22 is largely set back, the connection between the interconnection 22 and the conductor plug 20 can be ensured at least at the projection 20a.

An interconnection 28 is formed on the inter-layer insulation film 14 in the memory cell region 2. The end of the interconnection 28 and the end of the interconnection 22 are opposed to each other. One end of the interconnection 28 is connected to the conductor plug 26. The direction from one end of the interconnection 28 toward the inside thereof agrees with the second direction D2. In the semiconductor device according to the present embodiment, in which another interconnection 22 is formed opposed to the interconnection 28, it is impossible to form in advance the interconnection 28 longer in consideration of the set-back of the pattern of the interconnection 28. However, the conductor plug 26 has the projection 26a projected in the second direction D2, and the direction of one end of the interconnection 28 toward the inside thereof agrees with the second direction D2, whereby even when the pattern of the interconnection 28 is largely set back, the connection between the interconnection 28 and the conductor plug 26 can be ensured at least at the projection 32.

On the inter-layer insulation film 14 in the logic circuit region 4, an interconnection 52 is formed. In the logic circuit region 4, where the interconnection 52, etc. are not required to be formed essentially in high density, in comparison with the interconnection 22, 28 in the memory cell region 2, whereby the width of the interconnection 52 can be set larger than the interconnections 22, 28 and the margin of the pitch of the interconnection can be secured. Accordingly, the set-back of the interconnection 52 is not so large. It is also possible to form in advance the interconnection 52 longer in consideration of the set-back of the pattern of the interconnection 52. Thus, the interconnection 52 and the conductor plug 48 can be connected to each other without failure in the logic region 4.

Another inter-layer insulation film 54 is formed on the inter-layer insulation film 14 with the interconnections 22, 28, 52 formed on, covering the interconnections 22, 28, 52.

In the inter-layer insulation film 54, a contact hole 56 is formed down to the conductor plug 20. A conductor plug 58 is buried in the contact hole 56.

In the inter-layer insulation film 54, a contact hole 60 is formed down to the interconnection 28. A trench 62 which is shallower than the contact hole 60 is formed in the inter-layer insulation film 54. The trench 62 is formed, extended from the contact hole 60 in a second direction D2. The trench 62 is formed integral with the contact hole 60. A conductor plug 64 having a projection 64a projected in the trench 62 is formed in the trench 62 and the contact hole 60. The projection 64a is formed of one and the same conductor film as the conductor plug 64 integrally therewith. The projection 64a is projected in the second direction D2.

An interconnection 66 is formed on the inter-layer insulation film 54. The interconnection 66 is connected to the conductor plug 58.

An interconnection 68 is formed on the inter-layer insulation film 54. One end of the interconnection 68 is connected to the conductor plug 64. The direction of said end of the interconnection 68 toward the inside thereof agrees with the second direction D2. In the semiconductor device according to the present embodiment, in which the interconnection 66 is formed adjacent to the interconnection 68, it is impossible to form the interconnection 68 longer in consideration of the set-back of the pattern of the interconnection 68. However, the conductor plug 64 has the projection 64a projected in the second direction D2, and the direction form one end of the interconnection 68 toward the inside thereof agrees with the second direction D2, whereby even when the pattern of the interconnection 68 is set back largely, the connection between the interconnection 68 and the conductor plug 64 can be ensured at least at the projection 64a.

An interconnection 70 is formed on the inter-layer insulation film 54.

Another inter-layer insulation film 72 is formed on the inter-layer insulation film 54 with the interconnections 66, 68, 70 formed on, covering the interconnections 66, 68, 70.

Thus, the semi conductor device according to the present embodiment is constituted.

As described above, the interconnection 22 may be connected to the source/drain diffused layer 44b of the transistor 46a via the conductor plug 20. The interconnection 28 may be connected to the gate electrobe 40b of the transistor 46b via the conductor plug 26. The interconnection 68 may be connected to said another interconnection 28 via the conductor plug 64.

### (The Method for Fabricating the Semiconductor Device)

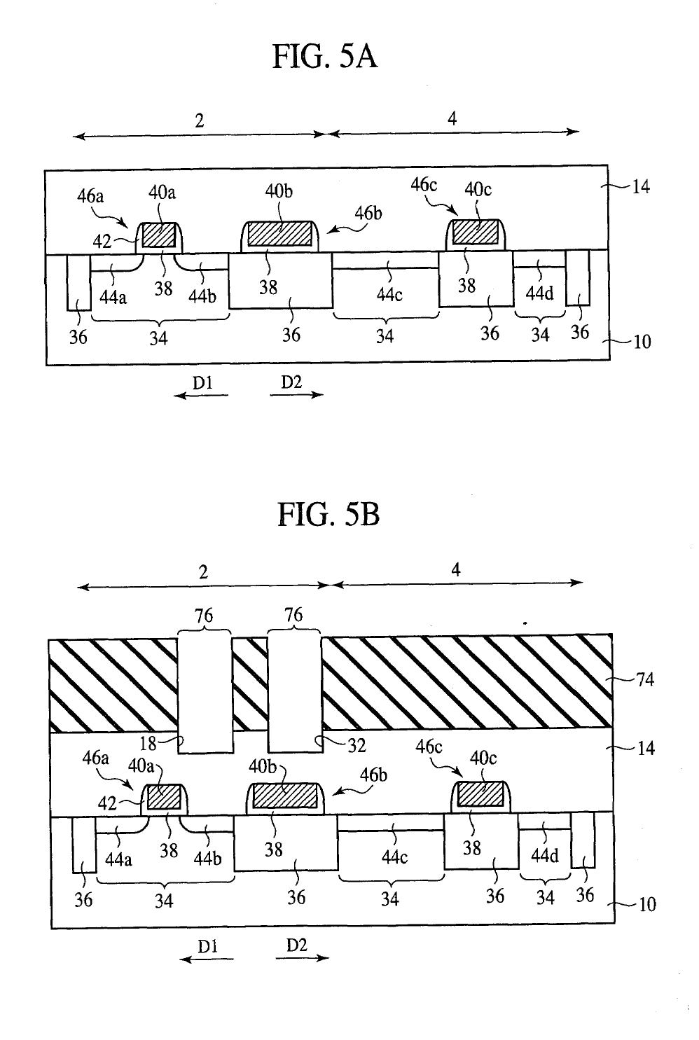

Next, the method for fabricating the semiconductor device according to the present embodiment will be explained with reference to FIGS. 5A to 11B. FIGS. 5A to 11B are sectional views of the semiconductor device according to the present embodiment in the steps of the method for fabricating the semiconductor device, which explain the method.

First, the semiconductor substrate 10 is prepared. The semiconductor substrate 10 is, e.g., a silicon substrate.

Then, the device isolation regions 36 are formed in the semiconductor substrate 10 by, e.g., STI (Shallow Trench Isolation). The device isolation regions 36 defined the device regions 34.

Next, the gate insulation film 38 is formed by, e.g., thermal oxidation. The film thickness of the gate insulation film 38 is, e.g., 2.0 nm.

Next, a polysilicon film is formed on the entire surface by, e.g., CVD. The film thickness of the polysilicon film is, e.g., 180 nm. Then, the polysilicon film is patterned by, e.g., photolithography. Thus, the gate electrodes 40a, 40b, 40c of the polysilicon are formed.

Next, with the gate electrodes 40 as the mask, a dopant impurity is implanted in the semiconductor substrate 10 on both sides of the gate electrodes 40 by, e.g., ion implantation. Thus, the impurity diffused regions forming the shallow regions of the extension source/drain structure, i.e., the extension regions (not illustrated) is formed.

Then, a silicon oxide film is formed on the entire surface by, e.g., CVD. The film thickness of the silicon oxide film is, e.g., 100 nm. Then, the silicon oxide film anisotropically etched. Thus, the sidewall insulation film 40 of the silicon oxide film is formed on the side walls of the gate electrodes 40.

Then, by using as the mask the gate electrodes 40 with the sidewall insulation film 42 formed on, a dopant impurity is implanted in the semiconductor substrate 10 on both sides of the gate electrodes 40 by, e.g., ion implantation. Thus, the impurity diffused regions (not illustrated) of the deep regions of the extension source/drain structure is formed. The impurity diffused regions (extension regions) of the shallow regions of the extension source/drain structure, and the impurity diffused regions of the deep regions of the extension source/drain structure formed the source/drain regions 44a, 44b, 44c, 44d of the extension source/drain structure.

Then, a 1100 nm-thickness silicon oxide film is formed by, e.g., CVD. Then, the surface of the silicon oxide film is polished by, e.g., CMP to planarize the surface of the silicon oxide film. Thus, the inter-layer insulation film 14 of the silicon oxide film of, e.g., an about 800 nm-thickness is formed (see FIG. 5A).

Next, a photoresist film 74 is formed on the entire surface by, e.g., spin coating.

Next, openings 76 are formed in the photoresist film 74 by photolithography. The openings 76 are for forming the trenches 18, 32 in the inter-layer insulation film 14.

Next, as illustrated in FIG. 5B, with the photoresist film 74 as the mask, the inter-layer insulation film 14 is dry etched to form the trenches 18, 32 in the inter-layer insulation film 14. The trench 18 is formed, extended in the first direction D1 from the position for the contact hole 16 to be formed in. The trench 32 is formed, extended in the second direction D2 from the position for the contact hole 30 to be formed in. The second direction D2 is opposite to the first direction D1. The depth of the trenches 18, 32 is, e.g., 200 nm. Then, the photoresist film 74 is released.

Next, a photoresist film 78 is formed on the entire surface by, e.g., spin coating.

Next, openings 80 are formed in the photoresist film 78 by photolithography. The openings 80 are for forming the contact holes 16, 30, 48 in the inter-layer insulation film 14.

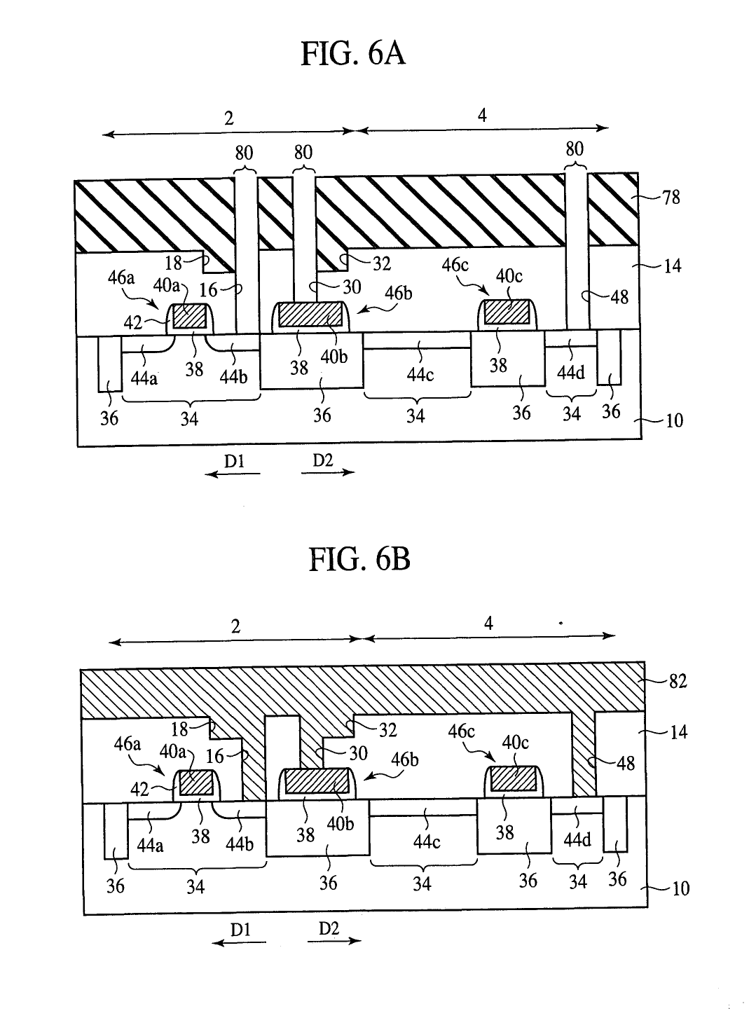

Next, with the photoresist film 78 as the mask, the inter-layer insulation film 14 is dry etched. The contact hole 16, the contact hole 30 and the contact hole 48 are formed respectively down to the source/drain diffused layer 44b, the gate electrode 40b and the source/drain diffused layer 44d. The contact holes 16, 30, 48 are formed deeper than the trenches 18, 32 (see FIG. 6A). Then, the photoresist film 78 is released (see FIG. 6B).

Then, an adhesion layer (not illustrated) is formed by, e.g., CVD. The adhesion layer is, e.g., a titanium nitride film. The film thickness of the adhesion layer is, e.g., 60 nm. The adhesion layer is for ensuring the adhesion of the conductor plugs to the lower layer.

Next, the conductor film 82 is formed by, e.g., CVD. The conductor film 82 is, e.g., a tungsten film. The film thickness of the conductor film 82 is, e.g., 300 nm. The conductor film 82 is to form the conductor plugs 20, 26, 50.

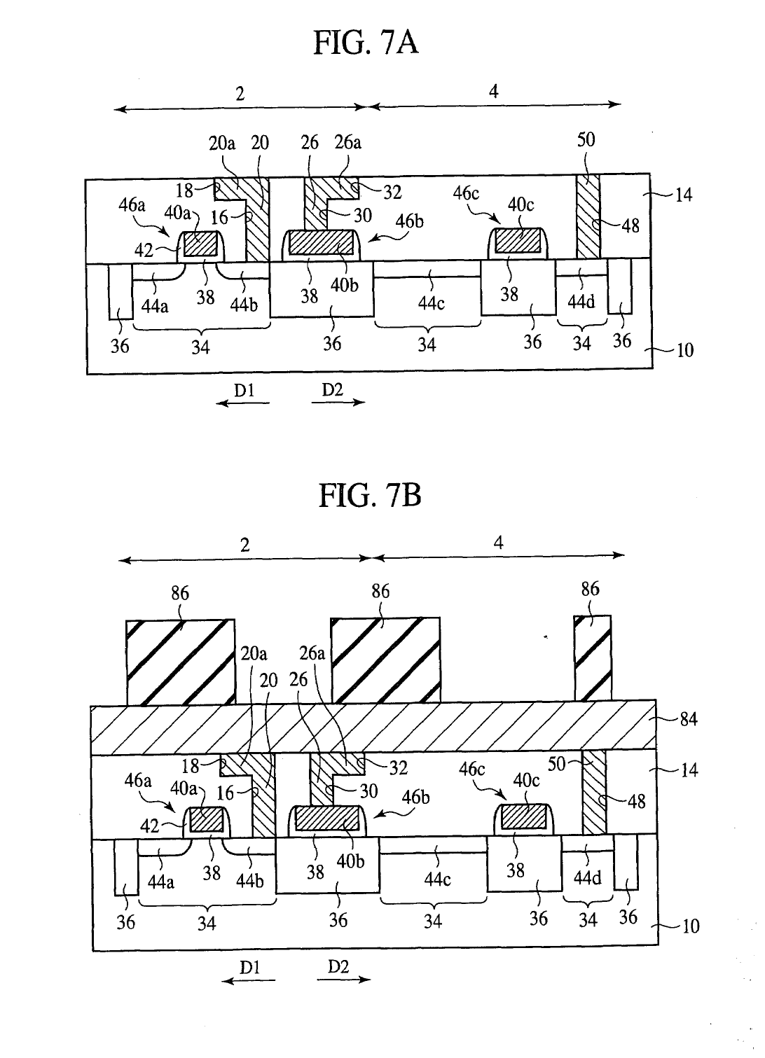

Then, the conductor film 82 and the adhesion layer are polished by, e.g., CMP until the surface of the inter-layer insulation film 14 is exposed. Thus, the conductor plug 20 of the conductor film 82 is buried in the contact hole 16 and the trench 18. In the contact hole 30 and the trench 32, the conductor plug 26 of the conductor film 82 is buried. In the contact hole 48, the conductor plug 50 of the conductor film 82 is buried (see FIG. 7A).

Next, the conductor film 84 is formed on the entire surface by, e.g., sputtering. The conductor film 84 is a layer film of, e.g., an AlCu alloy film and a titanium nitride film. The conductor film 84 is to be the interconnections 22, 28, 52.

Then, a photoresist film 86 is formed on the entire surface by, e.g., spin coating.

Then, the photoresist film 86 is patterned by photolithography (see FIG. 7B). When the photoresist film 86 is exposed, the part which are not to be exposed are exposed by the diffracted light, which causes the set-back of the pattern.

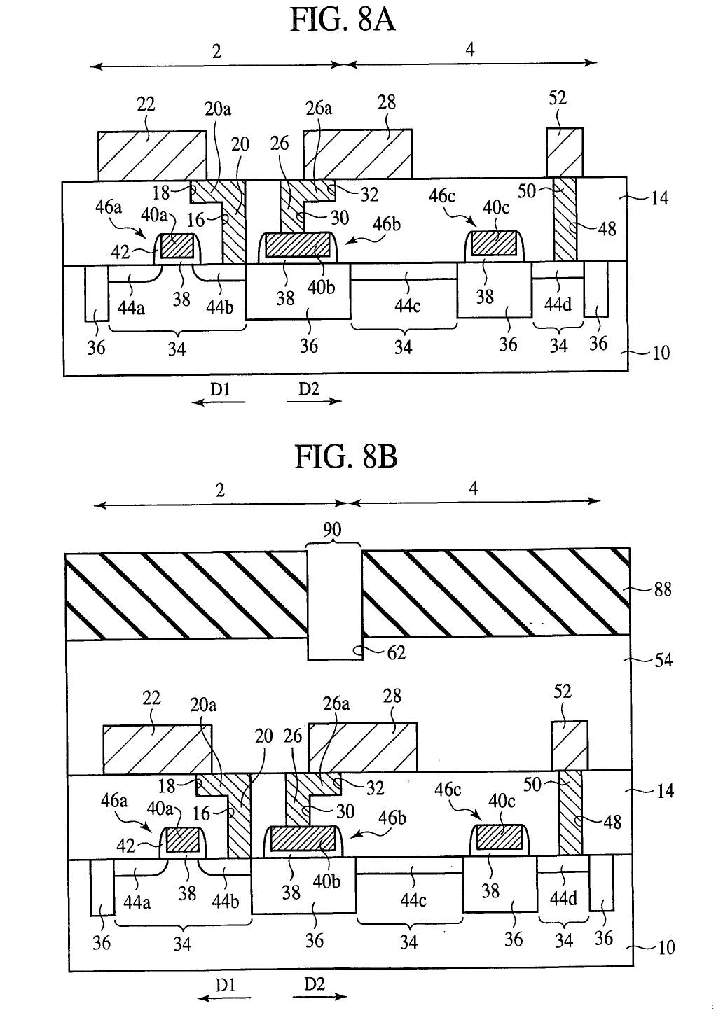

Then, the conductor film 84 is dry etched with the photoresist film 86 as the mask. Thus, the interconnections 22, 28, 52 of the conductor film 84 are formed (see FIG. 8A). The direction from one end of the interconnection 22 toward the inside thereof agrees with the direction D1, in which the projection 20a is projected, whereby the connection between the interconnection 22 and the conductor plug 20 is ensured at at least at the projection 20a. The direction from one end of the interconnection 28 toward the inside thereof agrees with the direction D2, in which the projection 26a is projected, whereby the connection between the interconnection 28 and the conductor plug 26a is ensured at least at the projection 26a.

Then, a 1800 nm-thickness silicon oxide film is formed by, e.g., CVD. Then, the surface of the silicon oxide film is polished by, e.g., CMP to thereby planarize the surface of the silicon oxide film. Thus, the inter-layer insulation film 54 of the silicon oxide film of, an about 800 nm-thickness is formed.

Next, a photoresist film 88 is formed on the entire surface by, e.g., spin coating.

Next, an opening 90 is formed in the photoresist film 88 by photolithography. The opening 90 is for forming a trench 62 in the inter-layer insulation film 54.

Next, with the photoresist film 88 as the mask, the inter-layer insulation film 54 is dry etched to thereby form the trench 62 in the inter-layer insulation film 54 (see FIG. 8B). The trench 62 is formed, extended in the second direction D2 from the position where the contact hole 60 is to be formed. The depth of the trench 62 is, e.g., 200 nm. Then, the photoresist film 88 is released.

Next, a photoresist film 92 is formed on the entire surface by, e.g., spin coating.

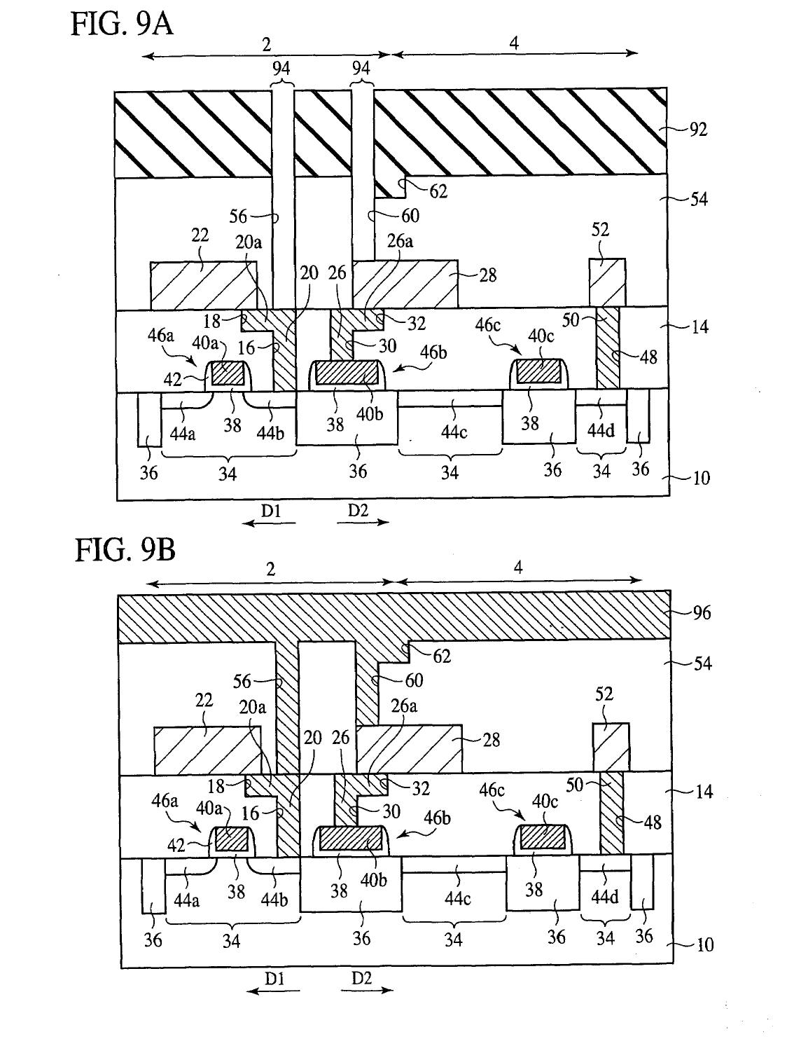

Next, openings 94 are formed in the photoresist film 92 by photolithography (see FIG. 9A). The openings 94 are for forming the contact holes 56, 60 in the inter-layer insulation film 54.

Next, with the photoresist film 92 as the mask, the inter-layer insulation film 54 is dry etched. Thus, the contact hole 56 and the contact hole 60 are formed respectively down to the conductor plug 20 and the interconnection 28. The contact holes 56, 60 are formed deeper than the trench 62. Then, the photoresist film 92 is released.

Next, the adhesion layer (not illustrated) is formed by, e.g., CVD. The adhesion layer is, e.g., a titanium nitride film. The film thickness of the adhesion layer is, e.g., 50 nm.

Next, as illustrated in FIG. 9B, the conduction film 96 is formed by, e.g., CVD. The conduction film 96 is, e.g., a tungsten film. The film thickness of the conduction film 96 is, e.g., 300 nm. The conductor film 96 is to be the conductor plugs 58, 64.

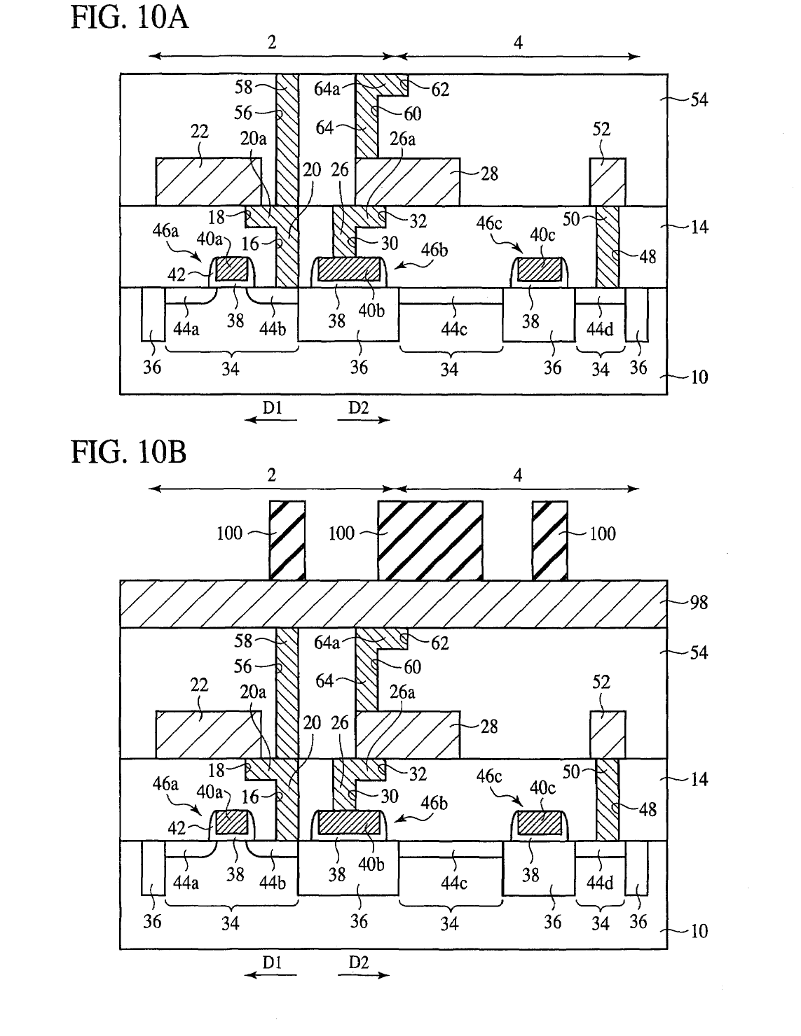

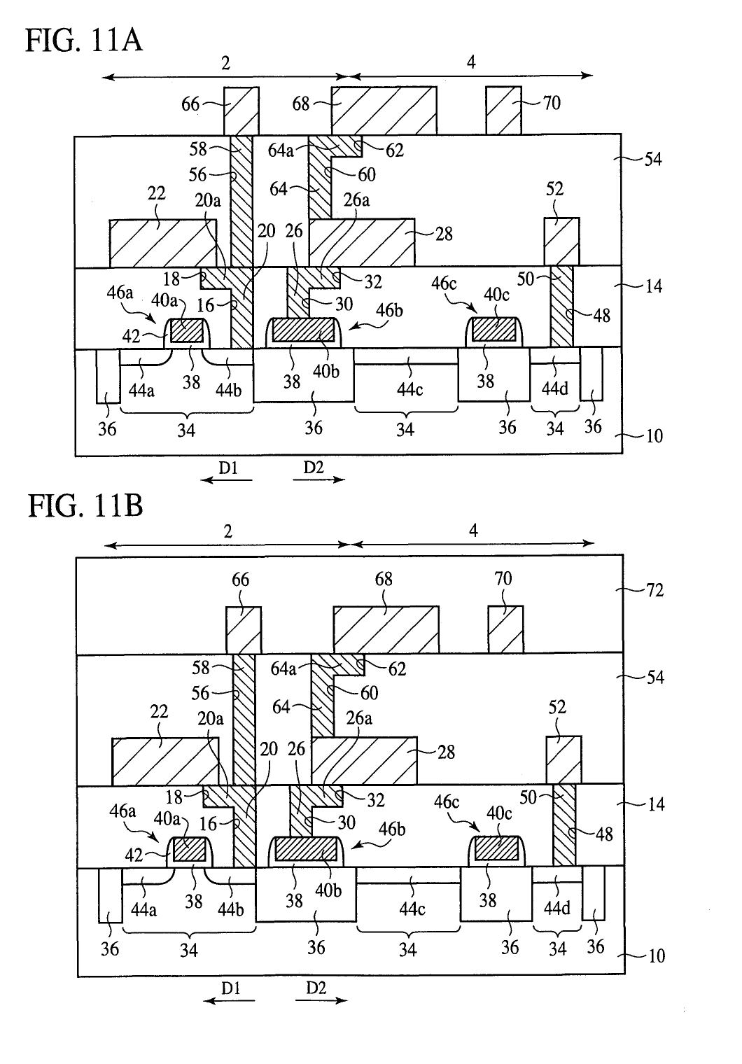

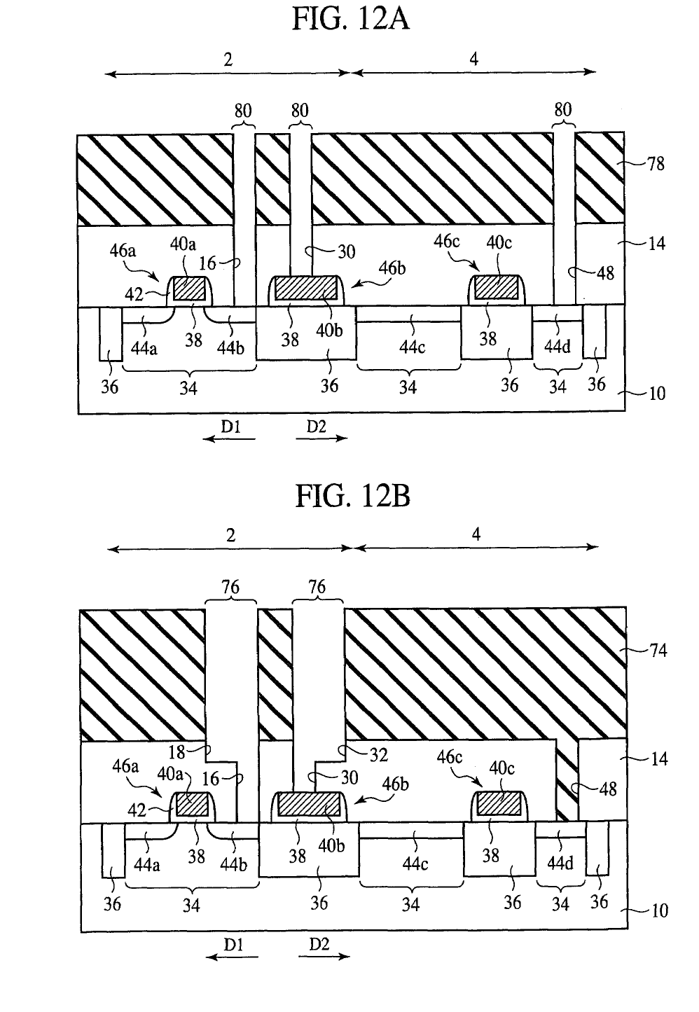

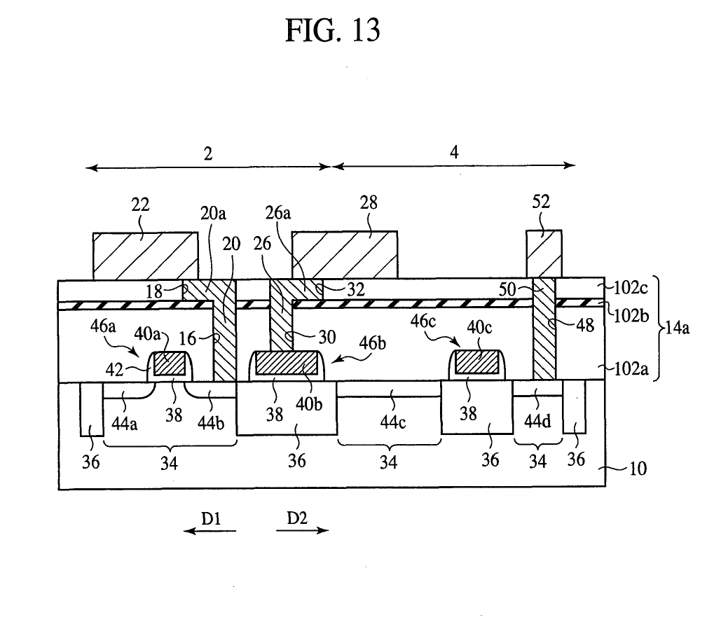

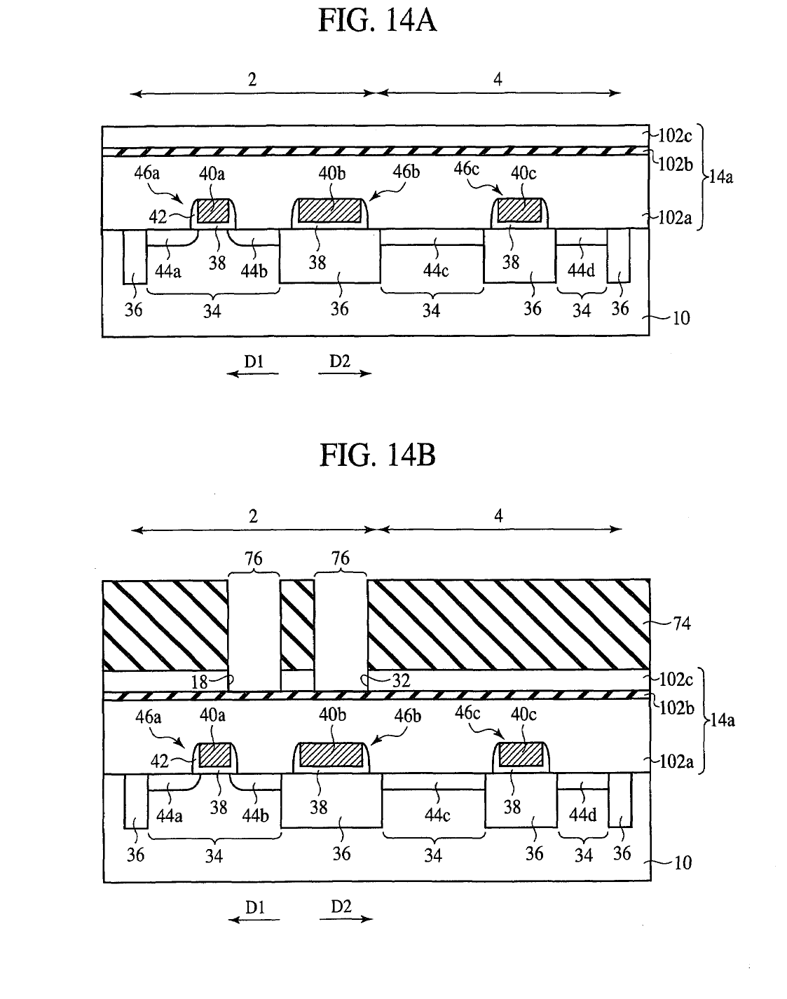

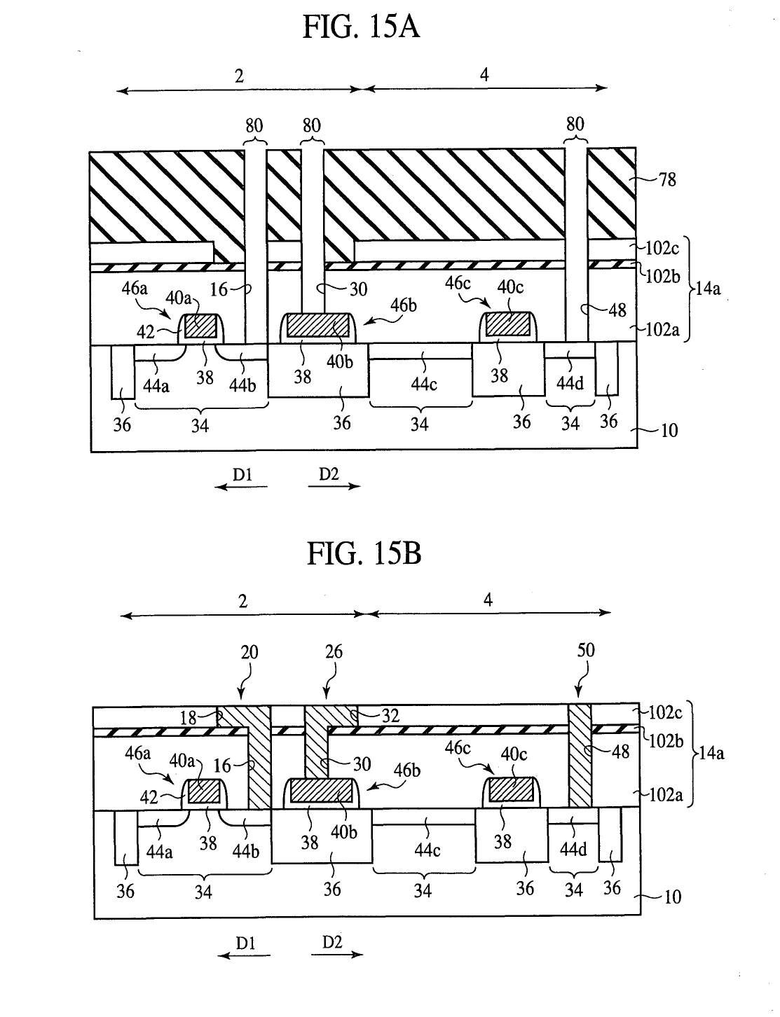

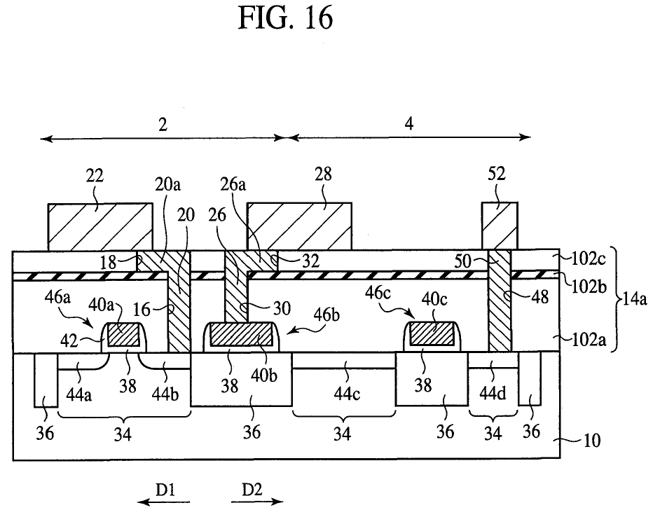

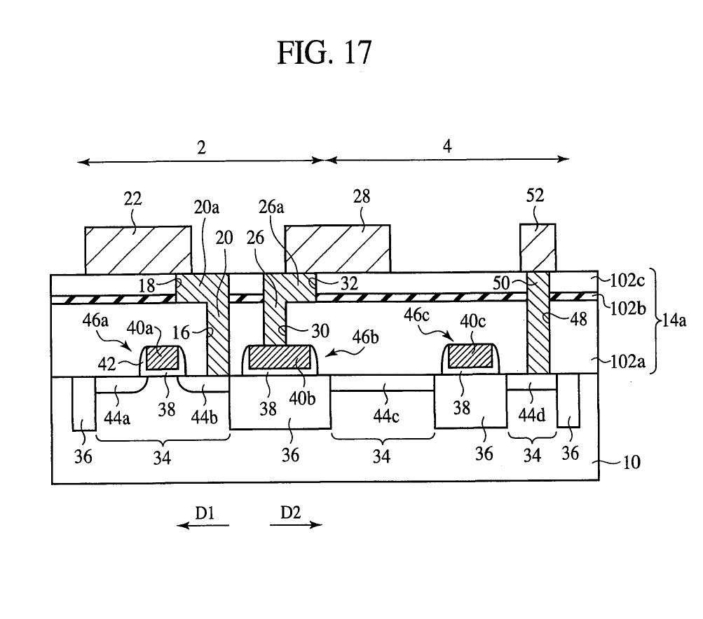

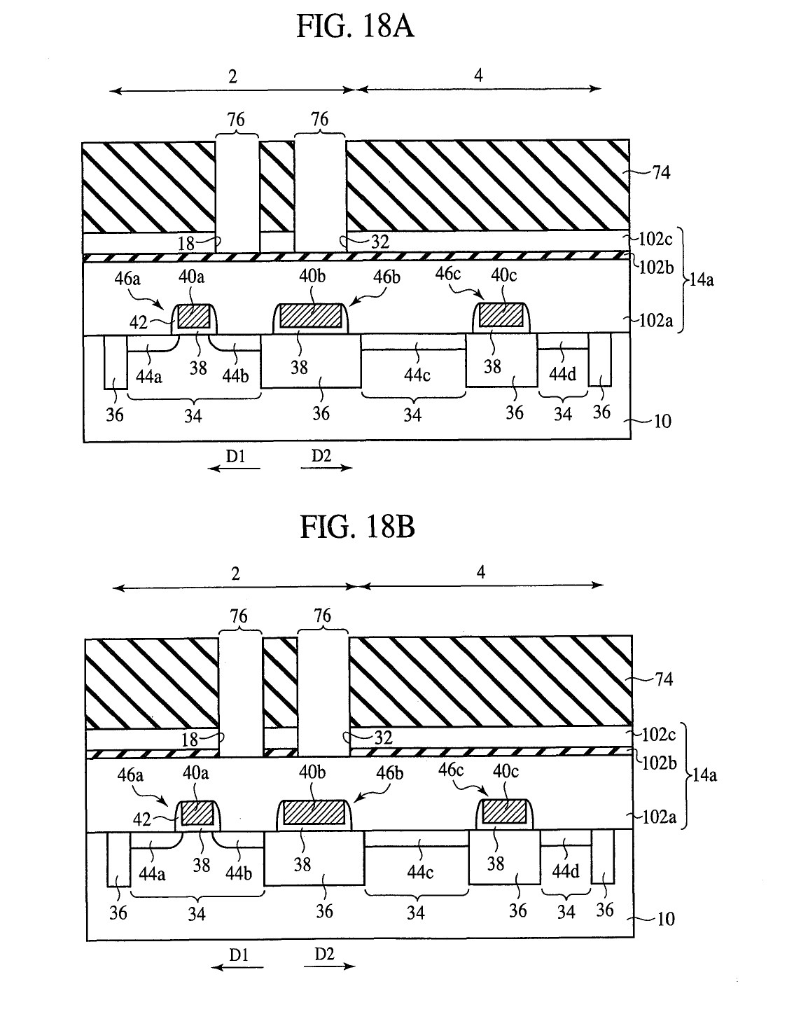

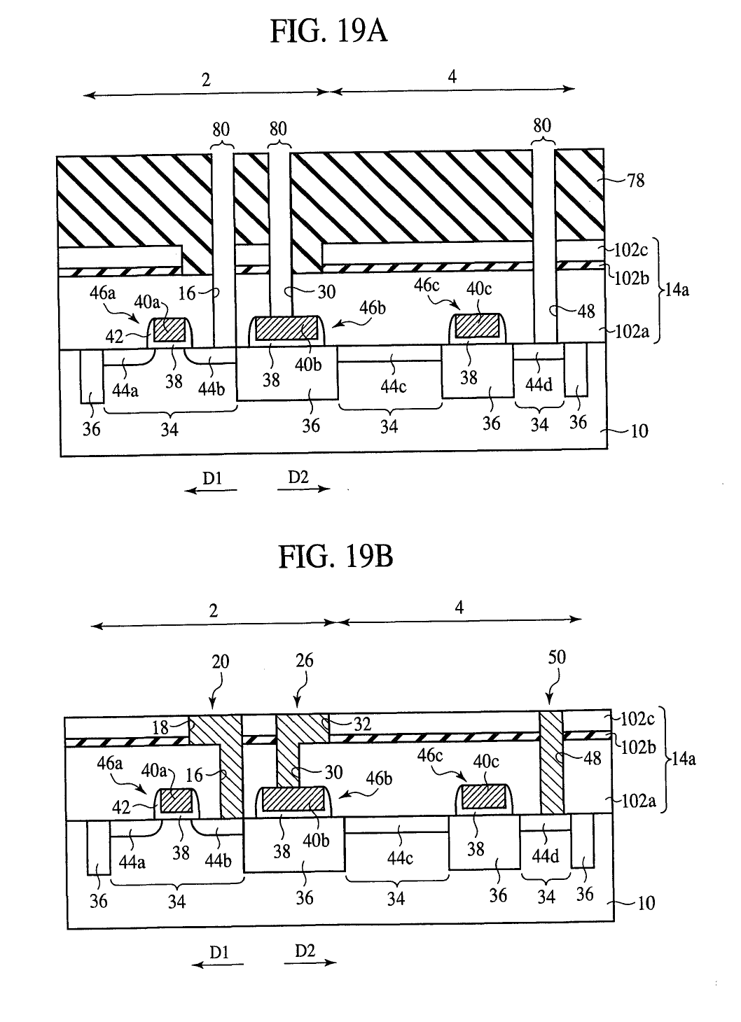

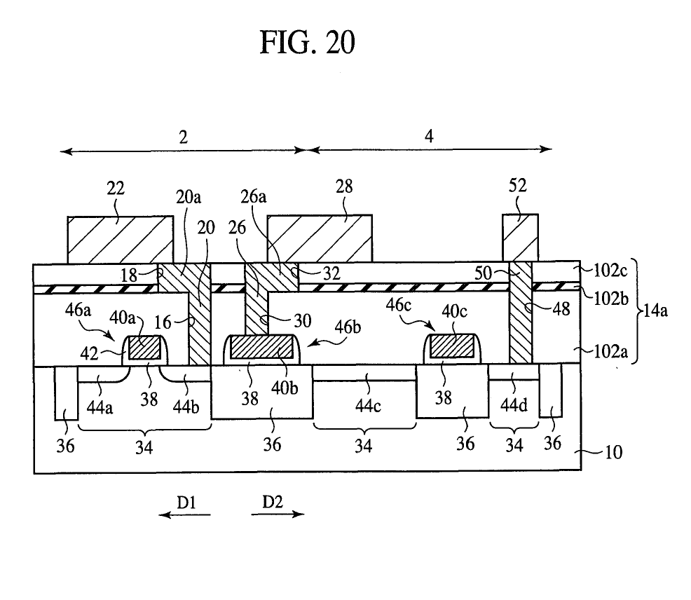

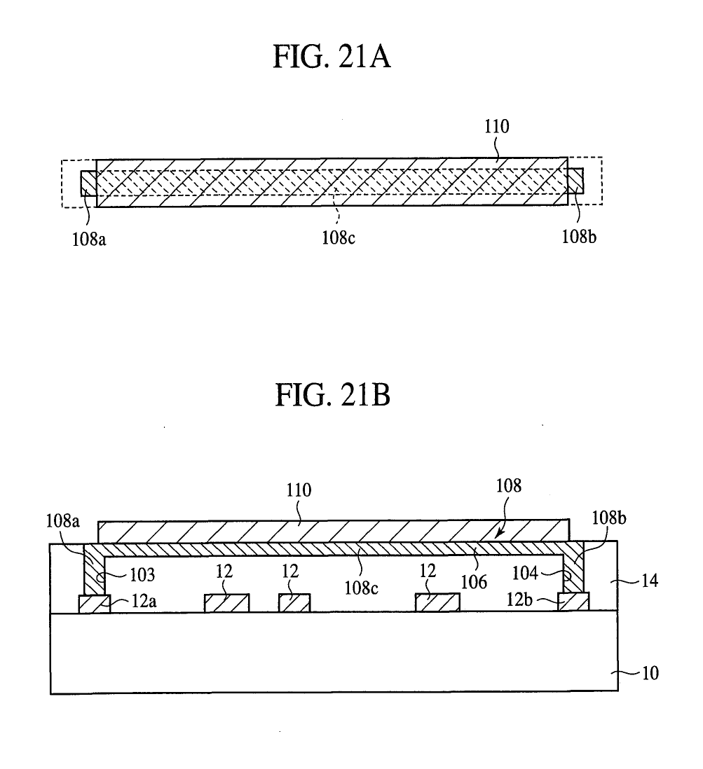

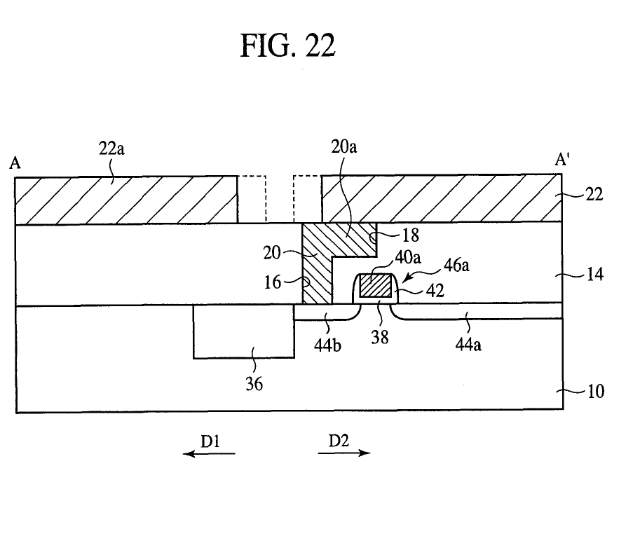

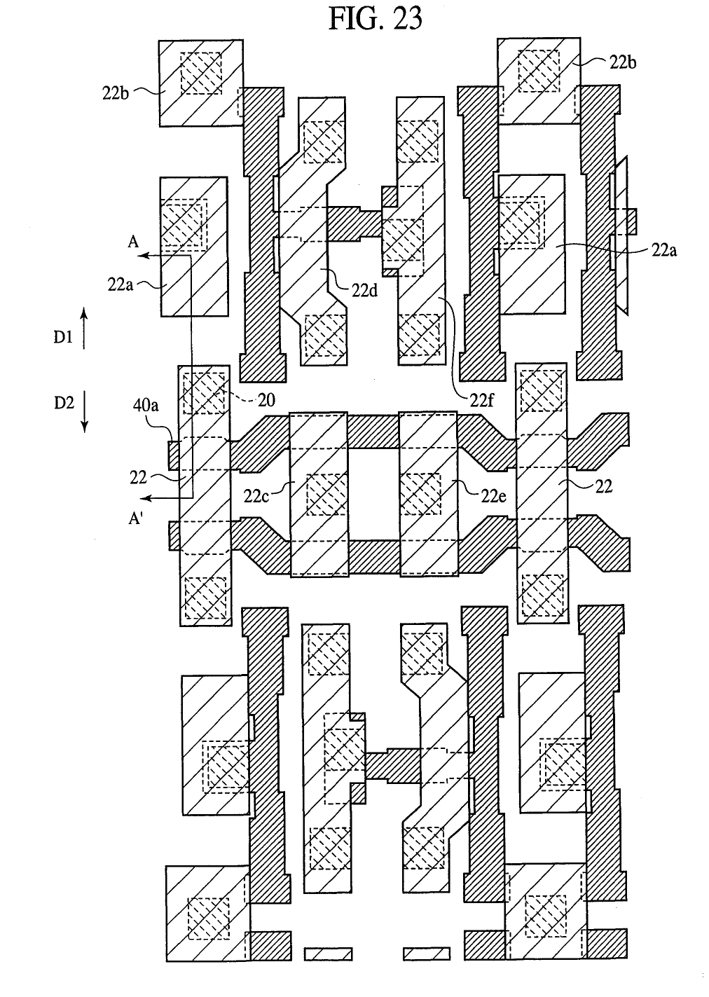

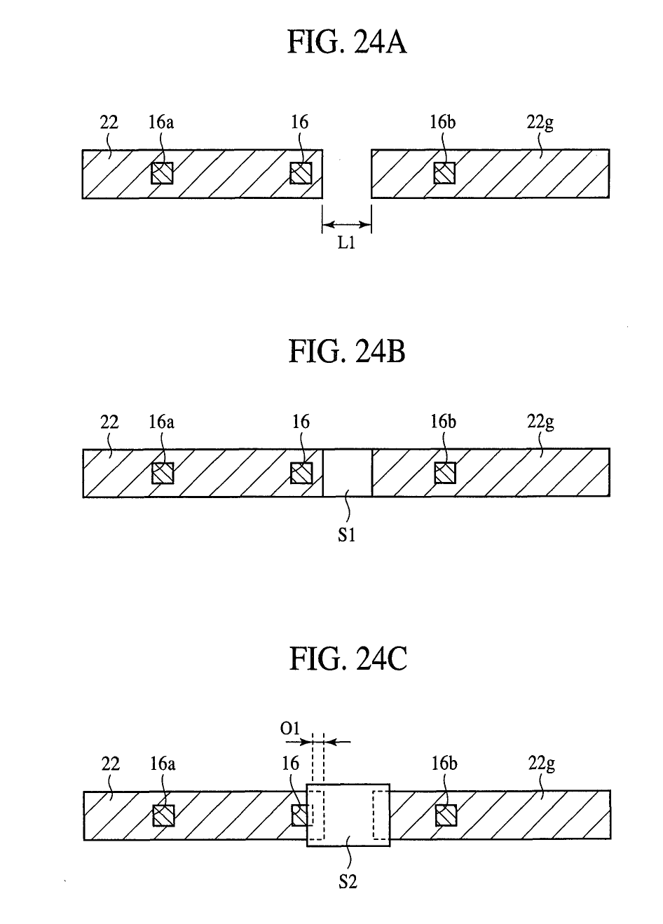

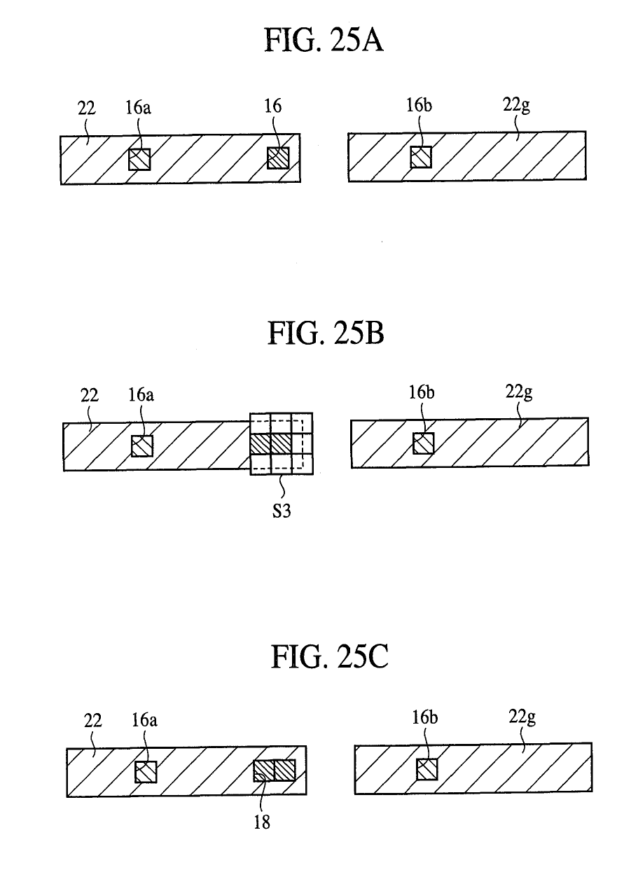

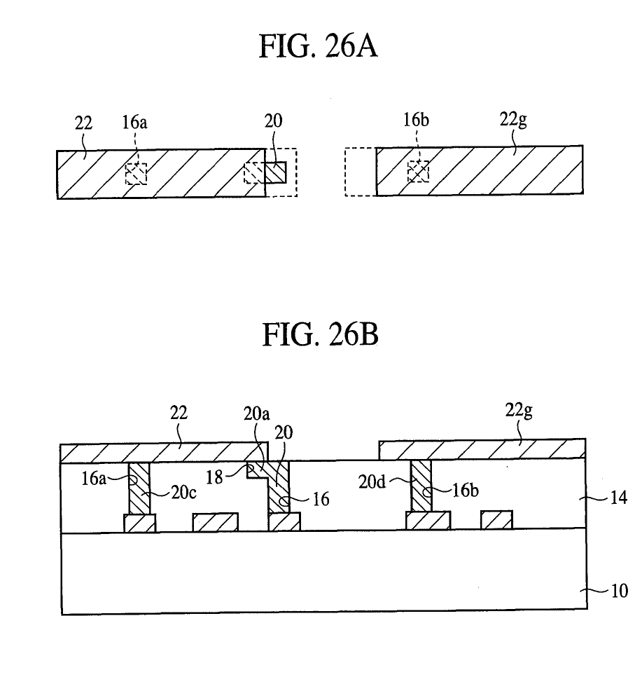

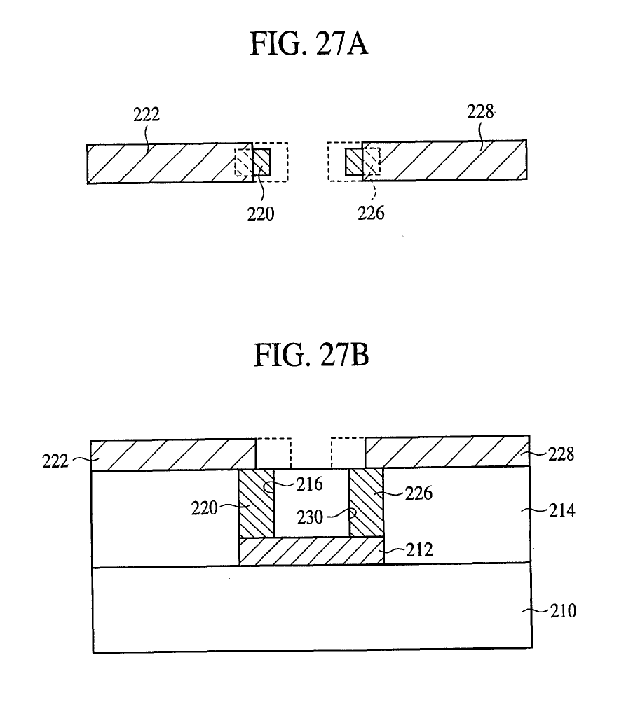

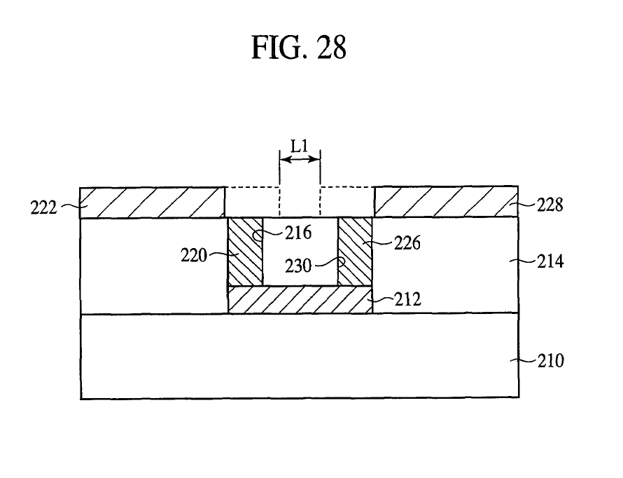

Then, the conductor film 96 and the adhesion layer are polished by, e.g., CMP until the surface of the inter-layer insulation film 54 is exposed. Thus, the conductor plug 58 of the conductor film 96 is buried in the contact hole 56. In the contact hole 60 and the trench 62, the conductor plug 64 of the conductor film 96 is buried (see FIG. 10A).

Next, the conductor film 98 is formed on the entire surface by, e.g., sputtering. The conductor film 98 is a layer film of, e.g., an AlCu alloy film and a titanium nitride film.

Then, a photoresist film 100 is formed on the entire surface by, e.g., spin coating.

Then, the photoresist film 100 is patterned by photolithography (see FIG. 10B). In patterning the photoresist film 100, the pattern is set back due to the diffracted light.

Next, with the photoresist film 100 as the mask, the conductor film 98 is dry etched. Thus, the interconnections 66, 68, 70 of the conductor film 98 (see FIG. 11A) are formed. The direction from one end of the interconnection 68 toward the inside thereof agrees with the direction D2, in which the projection 64a is projected, whereby the connection between the interconnection 68 and the conductor plug 64 is ensured at least at the projection 64a.

Next, a 1800 nm-thickness silicon oxide film is formed by, e.g., CVD. Then, the surface of the silicon oxide film is polished by, e.g., CMP to thereby planarize the surface of the silicon oxide film. Thus, the inter-layer insulation film 72 of the silicon oxide film of an about 800 nm-thickness is formed (see FIG. 11B).

Thus, the semiconductor device according to the present embodiment is fabricated.

### (A Modification of the Method for Fabricating the Semiconductor Device)

Next, a modification of the method for fabricating the semiconductor device according to the present embodiment will be explained with reference to FIGS. 12A and 12B. FIGS. 12A and 12B are sectional views of the semiconductor device in the steps of the modification of the method for fabricating the semiconductor device according to the present embodiment, which explain the method.

The steps up to the steps of forming the inter-layer insulation film 14 including the inter-layer insulation film 14 forming step are the same as those of the method for fabricating the semiconductor device described above with reference to FIG. 5A, and their explanation will not be repeated.

Next, the photoresist film 78 is formed on the entire surface by, e.g., spin coating.

Next, the openings 80 are formed in the photoresist film 78 by photolithography (see FIG. 12A). The openings 80 are for forming the contact holes 16, 30, 48 in the inter-layer insulation film 14.

Then, with the photoresist film 78 as the mask, the inter-layer insulation film 14 is dry etched. Thus, the contact hole 16 and the contact hole 30 and the contact hole 48 are formed respectively down to the source/drain diffused layer 44b, the gate electrode 40b and the source/drain diffused layer 44d. Then, the photoresist film 78 is released.

Next, the photoresist film 74 is formed on the entire surface by, e.g., spin coating.

Next, openings 76 are formed in the photoresist film 74 by photolithography. The openings 76 are for forming the trenches 18, 32 in the inter-layer insulation film 14.

Next, with the photoresist film 74 as the mask, the inter-layer insulation film 14 is dry etched. Thus, the trenches 18, 32 are formed in the inter-layer insulation film 14. The trench 18 is formed, extended from the contact hole 16 in the first direction D1. The trench 32 is formed, extended in the second direction D2 from the contact hole 30. The second direction D2 is opposite to the first direction D1. The depth of the trenches 18, 32 is, e.g., 200 nm. Then the photoresist film 74 is released.

The following steps of the modification of the semiconductor device fabricating method are the same as those of the method for fabricating the semiconductor device described above with reference to FIGS. 6B to 11B, and their explanation will not be repeated.

Thus, the semiconductor device according to the present embodiment is fabricated.

As described above, the trenches 18, 32 may be formed after the contact hole 16, 30, 48 have been formed.

### A FIFTH EMBODIMENT

The semiconductor device according to a fifth embodiment of the present invention and the method for fabricating the semiconductor device will be explained with reference to FIGS. 13 to 16. FIG. 13 is a sectional view of the semiconductor device according to the present embodiment. The same members of the present embodiment as those of the semiconductor device according to the first to the fourth embodiments and the method for fabricating the semiconductor device illustrated in FIGS. 1A to 12B are represented by the same reference numbers not to repeat or to simplify their explanation.

### (The Semiconductor Device)

First, the semiconductor device according to the present embodiment will be explained with reference to FIG. 13.

The semiconductor device according to the present embodiment is characterized mainly in that an etching stopper film 102b is formed in an inter-layer insulation 14a so that when trenches 18, 32 are formed by etching, the etching can be stopped at a desired depth.

As illustrated in FIG. 13, on a semiconductor substrate 10 with transistors 46 formed on, a first insulation film 102a is formed. The first insulation film 102a is, e.g., a silicon oxide film. The film thickness of the first insulation film 102a is, e.g., 600 nm.

A second insulation film 102b having etching characteristics different from those of the first insulation film 102a is formed on the first insulation film 102a. The second insulation film 102b is, e.g., a silicon nitride film. The film thickness of the second insulation film 102b is, e.g., 50 nm.

A third insulation film 102c having etching characteristics different form those of the second insulation film 102b is formed on the second insulation film 102b. The third insulation film 102c is, e.g., a silicon oxide film. The film thickness of the third insulation film 102c is, e.g., 200 nm.

The first insulation film 102a, the second insulation film 102b and the third insulation film 102c form the inter-layer insulation film 14a.

The trenches 18, 32 are formed in the third insulation film 102c down to the second insulation film 102b. A conductor plug 20 is buried in the trench 18 and the contact hole 16. A conductor plug 26 is buried in the trench 32 and the contact hole 30. A conductor plug 48 is buried in the contact hole 50.

Interconnections 22, 28, 52 are formed on the inter-layer insulation film 14a.

Thus, the semiconductor device according to the present embodiment is constituted.

### (The Method for Fabricating the Semiconductor Device)

Next, the method for fabricating the semiconductor device according to the present embodiment will be explained with reference to FIGS. 14A to 16. FIGS. 14A to 16 are sectional views of the semiconductor device according to the present embodiment in the steps of the method for fabricating the semiconductor device, which illustrate the method.

The steps up to the step of forming the transistors 46 are the same as those of the semiconductor device fabricating method described above with reference to FIG. 5A, and their explanation will not be repeated.

Next, on the semiconductor substrate 10 with the transistors 46 formed on, a silicon oxide film is formed by, e.g., CVD. Then, the surface of the silicon oxide film is polished by, e.g., CMP to thereby planarize the surface of the silicon oxide film. Thus, the first insulation film 102a of the silicon oxide film of an about 600 nm-thickness is formed.

Next, on the first insulation film 102a, the second insulation film 102b having etching characteristics different from those of the first insulation film 102a is formed by, e.g., CVD. The second insulation film 102b is, e.g., a silicon nitride film. The film thickness of the second insulation film 102b is, e.g., 50 nm. The second insulation film 102b functions as the etching stopper film in etching the third insulation film 102c to thereby form the trenches 18, 32 in a later step.

Then, on the second insulation film 102b, a third insulation film 102c having etching characteristics different from those of the second insulation film 102b is formed by, e.g., CVD. The third insulation film 102c is, e.g., a silicon oxide film. The film thickness of the third insulation film 102c is, e.g., 200 nm.

Thus, the first insulation film 102a, the second insulation film 102b and the third insulation film 102c form the inter-layer insulation film 14a (see FIG. 14A).

Next, a photoresist film 74 is formed on the entire surface by, e.g., spin coating.

Next, openings 76 are formed in the photoresist film 74 by photolithography. The openings 76 are for forming the inter-layer insulation film 14a in the trenches 18, 32.

Next, with the photoresist film 74 as the mask and with the second insulation film 102b as the etching stopper, the third insulation film 102c is dry etched to thereby form the trenches 18, 32 in the third insulation film 102c (see FIG. 14B). The trench 18 is formed, extended in the first direction D1 from the position where the contact hole 16 is to be formed. The trench 32 is formed, extended in the second direction D2 from the position where the contact hole 30 is to be formed. The second direction D2 is opposite to the first direction D1. Because of the second insulation film 102b, which functions as the etching stopper, the film thickness of the third insulation film 102c is suitably set, whereby the trenches 18, 32 can be formed in a desired depth. Then, the photoresist film 74 is released.

Next, a photoresist film 78 is formed on the entire surface by, e.g., spin coating.

The openings 80 are formed in the photoresist film 78 by photolithography. The openings 80 are for forming the contact holes 16, 30, 48 in the inter-layer insulation film 14a.

Then, with the photoresist film 78 as the mask, the second insulation film 102b and the first insulation film 102a are dry etched. Thus, the contact hole 16, the contact hole 30 and the contact hole 48 are formed respectively down to the source/drain diffused layer 44b, the gate electrode 40b and source/drain diffused layer 44d (see FIG. 15A). Then, the photoresist film 78 is released.

Then, in the same way as in the semiconductor device fabricating method described above with reference to FIG. 6B and FIG. 7A, the conductor plug 20, the conductor plug 26 and the conductor plug 50 are buried respectively in the trench 18 and the contact hole 16, in the trench 32 and the contact hole 30, and in the contact hole 48 (see FIG. 15B).

The following steps of the semiconductor device fabricating method are the same as those of the semiconductor device fabricating method described above with reference to FIGS. 7B and 8A, and their explanation will not be repeated.

Thus, the semiconductor device according to the present embodiment is fabricated (see FIG. 16).

In the present embodiment, the third insulation film 102c is etched with the second insulation film 102b as the etching stopper to form the trenches 18, 32, whereby the trenches 18, 32 can be formed in a desired depth. Thus, the present embodiment can fabricate the semiconductor device of higher reliability.

### (Modification)

Next, the semiconductor device according to a modification of the present embodiment and the method for fabricating the semiconductor device will be explained with reference to FIGS. 17 to 20. FIG. 17 is a sectional view of the semiconductor device according to the present modification. FIGS. 18A to 20 are sectional views of the semiconductor device according to the present embodiment in the steps of the method for fabricating the semiconductor device, which explain the method.

First, the semiconductor device according to the present modification will be explained with reference to FIG. 17.

The semiconductor device according to the present modification is characterized mainly in that the second insulation film 102b is etched with the first insulation film 102a as the etching stopper, whereby the trenches 18, 32 are formed deeper.

As illustrated in FIG. 17, in the second insulation film 102b and the third insulation film 102c, the trenches 18, 32 are formed down to the first insulation film 102a. The conductor plug 20 is formed in the trench 18 and the contact hole 16. The conductor plug 26 is buried in the trench 32 and the contact hole 30. The conductor plug 48 is buried in the contact hole 50.

The interconnections 22, 28, 52 are formed on the inter-layer insulation film 14a.

Thus, the semiconductor device according to the present embodiment is constituted.

Then, the method for fabricating the semiconductor device according to the present embodiment will be explained with reference to FIGS. 18A to 20.

The steps up to the step of dry etching the third insulation film 102c with the photoresist film 74 as the mask and the second insulation film 102b as the etching stopper to thereby form the trenches 18, 32 in the third insulation film 102c including said step are the same as those of the semiconductor device fabricating method described above with reference to FIGS. 14A and 14B, and their explanation will not be repeated (see FIG. 18A).

Then, with the photoresist film 74 as the mask and the first insulation film as the etching stopper, the second insulation film 102b is dry etched. Thus, the trenches 18, 32 are formed down to the first insulation film 102a. Then, the photoresist film 74 is released.

Next, a photoresist film 78 is formed on the entire surface by, e.g., spin coating.

Then, the openings 80 are formed in the photoresist film 78 by photolithography. The openings 80 are for forming the contact holes 16, 30, 48 in the inter-layer insulation film 14a.

Then, with the photoresist film 78 as the mask, the first insulation film 102a is dry etched. Thus, the contact hole 16 and the contact hole 30 and the contact hole 48 are formed respectively down to the source/drain diffused layer 44b, the gate electrode 40b and the source/drain diffused layer 44d (see FIG. 19A). Then, the photoresist film 78 is released.

Then, in the same way as in the semiconductor device fabricating method described above with reference to FIGS. 6B and 7A, the conductor plug 20 is buried in the trench 18 and the contact hole 16, the conductor plug 26 is buried in the trench 32 and the contact hole 30, and the conductor plug 50 is buried in the contact hole 48 (see FIG. 19B).

The following process of the semiconductor device fabricating method is the same as that of the semiconductor device fabricating method described above with reference to FIGS. 7B and 8A, and its explanation will not be repeated.

Thus, the semiconductor device according to the present embodiment is fabricated (see FIG. 20).

As described above, it is also possible that the third insulation film 102c is etched with the second insulation film 102b as the etching stopper, and then the second insulation film 102b is etched with the first insulation film 102a at the etching stopper, whereby the trenches 18, 32 are formed deeper.

### A SIXTH EMBODIMENT

The semiconductor device according to a sixth embodiment of the present invention and the method for fabricating the semiconductor device will be explained with reference to FIGS. 21A and 21B. FIGS. 21A and 21B are diagrammatic views of the semiconductor device according to the present embodiment. FIG. 21A is a plan view and the FIG. 21B is a sectional view. The same members of the present embodiment as those of the semiconductor device according to the first to the fifth embodiments and the method for fabricating the semiconductor device illustrated in FIGS. 1A to 20 are represented by the same reference numbers not to repeat or to simplify their explanation.

The semiconductor device according to the present embodiment is characterized mainly in that a trench 106 is formed, connecting a contact hole 103 and another contact hole 104 with each other, a conductor plug 108a, a conductor plug 108b and a conductor plug 108c are buried integral with each other respectively in the contact hole 103, the contact hole 104 and the trench 106, and an interconnection 110 is formed along the trench 106.

As illustrated in FIGS. 21A and 21B, interconnections 12 are formed on a semiconductor substrate 10.

An inter-layer insulation film 14 is formed on the semiconductor substrate 10 with the interconnections 12 formed on.

In the inter-layer insulation film 14, the contact hole 103 down to the interconnection 12a is formed. In the inter-layer insulation film 14, the contact hole 104 down to the interconnection 12b is formed. In the inter-layer insulation film 14, the trench 106 is formed, connecting the contact hole 103 and the contact hole 104 with each other. The trench 106 is formed shallower than the contact holes 103, 104. The conductor plug 108a is buried in the contact hole 103. The conductor plug 108b is buried in the contact hole 104. The linear conductor 108c is buried in the trench 106. The conductor plug 108a, the conductor plug 108b and the conductor 108c are formed of one and the same conductor film integral with each other.

The interconnection 110 is formed on the inter-layer insulation film 14 with the conductor plugs 108a, 108b and the conductor 108c buried in. The interconnection 110 is formed along the trench 106.

Thus, the semiconductor device according to the present embodiment is constituted.

The semiconductor device according to the present embodiment is characterized mainly in that, as described above, the trench 106 is formed, connecting the contact hole 103 and another contact hole 104 with each other, and the conductor plugs 108a, 108b and the conductor 108c are buried in the contact holes 103, 104 and the trench 106 integral with each other, and the interconnection 110 is formed along the trench 106.

According to the present embodiment, because the interconnection 110 is formed along the trench 106, even when the pattern of the interconnection 110 is largely set back, the connection between the interconnection 110 and the conductor plugs 108 can be ensured at least at the conductor 108c buried in the trench 106. Furthermore, according to the present embodiment, the conductor 108c, which is buried in the trench 106 below the interconnection 110, can contribute to decreasing the resistance of the interconnection.

### A SEVENTH EMBODIMENT

The semiconductor device according to a seventh embodiment of the present invention and the method for fabricating the semiconductor device will be explained with reference to FIGS. 22 and 23. FIG. 22 is a sectional view of the semiconductor device according to the present embodiment. FIG. 23 is a plan view of the semiconductor device according to the present embodiment. FIG. 22 is the sectional view along the line A-A′ in FIG. 23. The same members of the present embodiment as those of the semiconductor device according to the first the sixth embodiments and the method for fabricating the semiconductor device illustrated in FIGS. 1A to 21B are represented by the same reference numbers not to repeat or to simplify their explanation.

The semiconductor device according to the present embodiment is characterized mainly in that the principle of the present invention is applied to the memory cell unit of an SRAM.

As illustrated in FIG. 22, in an inter-layer insulation film 14 a contact hole 16 is formed down to the source/drain diffused layer 44b of a transistor 46a. A trench 18 is formed in the inter-layer insulation film 14. The trench 18 is formed integral with the contact hole 16. The trench 18 is formed, extended from the contact hole 16 in the second direction D2. A conductor plug 20 is buried in the trench 18 and the contact hole 16.

On the inter-layer insulation film 14 with the conductor plug 20 buried in, interconnections 22, 22a, 22b, 22c are formed. The interconnection 22 and the interconnection 22a are formed, opposed to each other. The direction from one end of the interconnection 22 toward the inside thereof agrees with the second direction D2. The interconnections 22a-22f formed near the interconnection 22 make it difficult to design the interconnection 22 to be longer in consideration of the set-back of the pattern thereof. It is an idea to shorten the length of the interconnection 22a, but it makes it impossible to satisfy the design rules of the interconnection 22a. In the present embodiment, because the direction from one end of the interconnection 22 toward the inside thereof agrees with the direction D2 in which the projection 20a of the conductor plug 20 is projected, even when the pattern of the interconnection 22 is largely set back, the connection between the interconnection 22 and the conductor plug 20 can be ensured at least at the projection 20a.

### AN EIGHTH EMBODIMENT

The mask pattern forming method according to the eighth embodiment of the present invention will be explained with reference to FIGS. 24A to 26B. FIGS. 24A to 25C are conceptual views of a mask pattern in the steps of the mask pattern forming method according to the present embodiment. The same members of the present embodiment as those of the semiconductor device according to the first to the seventh embodiments and the method for fabricating the semiconductor device are represented by the same reference numbers not to repeat or to simplify their explanation.

The mask pattern forming method according to the present embodiment is used in forming a mask pattern for forming the trenches.

FIG. 24A shows the positions where contact holes 16, 16a, 16b and interconnections 22, 22g are to be formed. A large number of the contact holes 16, 16a, 16b and the interconnections 22, 22g are formed, but in FIG. 24A, only parts of a number of the contact holes 16, 16a, 16b and a number of interconnections 22, 22g are shown.

First, a region S1 where the gap L1 between the interconnection 22 and the interconnection 22g is smaller than a prescribed value is extracted (see FIG. 24B). Thus, the region S1 where the interconnection 22 and the interconnection 22g are adjacent to each other is extracted.

Next, the extracted region S1 is enlarged to thereby set a region S2. When the region S2 is set, the region S2 is set to exceed the overlap amount between the interconnection 22 and the contact hole 16.

Next, the contact hole 16 overlapping the region S2 is extracted (see FIG. 24C).

Thus, the contact hole 16 positioned near the region Si where the interconnection 22 and the interconnection 22g are adjacent to each other is extracted (see FIG. 25A).

Then, a region S3 which is centered on the extracted contact hole 16 and is larger than the contact hole 16 is set (see FIG. 25B) The region S3 is set to exceed the overlapping part between the interconnection 22 and the contact hole 16 and to be larger than the width of the interconnection 22. The size of the region S3 corresponds here to nine contact holes.

Next, the region where the region S3 and the interconnection 22 overlap each other is extracted (see FIG. 25c). Thus, the region where the trench 18 is to be formed is extracted.

Thus, the region for the trench is to be formed is extracted. Based on thus obtained data, a mask pattern for forming the trench is prepared.

FIGS. 26A and 26B are conceptual views of the semiconductor device fabricated by using the thus prepared mask pattern. FIG. 26A is a plan view, and FIG. 26B is a sectional view. The parts of the interconnections 22, 22g indicated by the broken lines are the patterns of the interconnections 22, 22g in the design stage.

In the contact hole 16 and the trench 18, the conductor plug 20 is buried. The conductor plug 20c is buried in the contact hole 16a. A conductor plug 20d is buried in the contact hole 16b.

As described above, according to the present embodiment, the position where the trench 18 to be formed can be easily extracted. Based on the thus obtained data, the mask pattern can be formed.

### MODIFIED EMBODIMENTS

The present invention is not limited to the above-described embodiments and can cover other various modifications.

For example, in the method for fabricating the semiconductor device according to the fifth embodiment, the contact holes 16, 30 are formed after the trenches 18, 32 have been formed, but the trenches 18, 32 may be formed after the contact holes 16, 30 have been formed.

What is claimed is:

1. A semiconductor device comprising:
a conductor plug;
another conductor plug arranged, spaced from the conductor plug;
a conductor formed integral with the conductor plug and said another conductor plug and connecting an upper part of the conductor plug and an upper part of said another conductor plug with each other; and
an interconnection formed along the conductor, the interconnection being connected directly to at least the conductor.

2. A semiconductor device according to claim 1, wherein
the conductor plug has a lower end connected to the gate electrode of a transistor or the source/drain. diffused layer thereof.

3. A semiconductor device according to claim 1, wherein
the conductor plug has a lower end connected to another interconnection.

4. A semiconductor device according to claim 1, wherein
the conductor plug is formed in a memory cell region.

5. A method for fabricating a semiconductor device comprising the steps of:
forming an insulation layer over a semiconductor substrate;
forming a contact hole in the insulation layer;
forming a trench integral with the contact hole in the insulation layer, the trench being shallower than the contact hole and extended from the contact hole in a first direction;
burying a conductor plug having a projection projected in the trench in the trench and the contact hole; and
forming a conductor film directly on the insulation layer and the conductor plug;
patterning the conductor film to form an interconnection of the conductor film having one end connected to at least the projection,
in the step of forming an interconnection, the interconnection being formed so that the direction from said one end of the interconnection toward the inside thereof agrees with the first direction.

6. A method for fabricating a semiconductor device comprising the steps of:
forming an insulation layer over a semiconductor substrate;
forming in the insulation layer a trench extended in a first direction from a first position;
forming a contact hole deeper than the trench integrally with the trench in the insulation layer at said first position;
burying a conductor plug having a projection projected in the trench in the contact hole and the trench;
forming a conductor film on the insulation layer and the contact layer; and
patterning the conductor film to form an interconnection of the conductor film having one end connected to at least the projection,
in the step of forming an interconnection, the interconnection being formed so that the direction from said one end of the interconnection toward the inside thereof agrees with the first direction.

7. A method for fabricating a semiconductor device comprising the steps of:
forming an insulation layer over a semiconductor substrate;
forming a first contact hole and a second contact hole in the insulation layer;
forming a trench integral with the first and the second contact holes in the insulation layer, the trench being shallower than the first and the second contact holes and extended from the first contact hole to the second contact hole;
burying a conductor plug in the first contact hole, burying another conductor plug in the second contact hole and burying a conductor in the trench;
forming a conductor film on the insulation layer, the conductor plug, said another conductor plug and the conductor; and
patterning the conductor film to form along the conductor an interconnection of the conductor film connected to at least the conductor.

8. A method for fabricating a semiconductor device comprising the steps of:
forming an insulation layer over a semiconductor substrate;
forming in the insulation layer a trench extended from a first position to a second position;
forming a first contact hole deeper than the trench integrally with the trench in the insulation layer at said first position and forming a second contact hole deeper than the trench integrally with the trench in the insulation layer at said second position;
burying a conductor plug in the first contact hole, burying another conductor plug in the second contact hole and burying a conductor in the trench;
forming a conductor film on the insulation layer, the conductor plug, said another conductor plug and the conductor; and
patterning the conductor film to form an interconnection of the conductor film along the conductor, connected to at least the conductor.

9. A method for fabricating a semiconductor device according to claim 5, wherein
the step of forming an insulation layer includes the step of forming a first film, the step of forming a second film having etching characteristics different from those of the first film, and the step of forming a third film having etching characteristics different from those of the second film; and
the step of forming a trench includes the step of etching the third film with the second film as an etching stopper to form the trench down to the second film.

10. A method for fabricating a semiconductor device according to claim 6, wherein
the step of forming an insulation layer includes the step of forming a first film, the step of forming a second film having etching characteristics different from those of the first film, and the step of forming a third film having etching characteristics different from those of the second film; and
the step of forming a trench includes the step of etching the third film with the second film as an etching stopper to form the trench down to the second film.

11. A method for fabricating a semiconductor device according to claim 7, wherein
the step of forming an insulation layer includes the step of forming a first film, the step of forming a second film having etching characteristics different from those of the first film, and the step of forming a third film having etching characteristics different from those of the second film; and
the step of forming a trench includes the step of etching the third film with the second film as an etching stopper to form the trench down to the second film.

12. A method for fabricating a semiconductor device according to claim 8, wherein
the step of forming an insulation layer includes the step of forming a first film, the step of forming a second film having etching characteristics different from those of the first film, and the step of forming a third film having etching characteristics different from those of the second film; and
the step of forming a trench includes the step of etching the third film with the second film as an etching stopper to form the trench down to the second film.

13. A method for fabricating a semiconductor device according to claim 9, wherein
the step of forming a trench further includes, after the step of forming the trench down to the second film, the step of etching the second film exposed in the trench with the first film as an etching stopper to form the trench down to the first film.

14. A method for fabricating a semiconductor device according to claim 10, wherein
the step of forming a trench further includes, after the step of forming the trench down to the second film, the step of etching the second film exposed in the trench with the first film as an etching stopper to form the trench down to the first film.

15. A method for fabricating a semiconductor device according to claim 11, wherein
the step of forming a trench further includes, after the step of forming the trench down to the second film, the step of etching the second film exposed in the trench with the first film as an etching stopper to form the trench down to the first film.

16. A method for fabricating a semiconductor device according to claim 12, wherein
the step of forming a trench further includes, after the step of forming the trench down to the second film, the step of etching the second film exposed in the trench with the first film as an etching stopper to form the trench down to the first film.

17. A method for fabricating a semiconductor device according to claim 9, wherein
the first film is a first silicon oxide film,
the second film is a silicon nitride film, and
the third film is a second silicon oxide film.

18. A method for fabricating a semiconductor device according to claim 10, wherein
the first film is a first silicon oxide film,
the second film is a silicon nitride film, and
the third film is a second silicon oxide film.

19. A method for fabricating a semiconductor device according to claim 11, wherein
the first film is a first silicon oxide film,
the second film is a silicon nitride film, and
the third film is a second silicon oxide film.

20. A method for fabricating a semiconductor device according to claim 12, wherein
the first film is a first silicon oxide film,
the second film is a silicon nitride film, and
the third film is a second silicon oxide film.
